(19) United States
(12) Patent Application Publication
(10) Pub. No.: US 2005/0139252 A1
(43) Pub. Date: Jun. 30, 2005

(54) Photovoltaic systems and methods

(76) Inventor: Youngtack Shim, Part Moody (CA)

Correspondence Address: Youngtack Shim, 155 Aspenwood Drive, Port Moody, BC, V3H 5A5, CA

(21) Appl. No.: 10/745,548

(22) Filed: Dec. 29, 2003

(51) Int. Cl. H01L 31/00

(52) U.S. Cl. 136/244; 136/255; 136/249

(57) ABSTRACT

The present invention generally relates to various photovoltaic systems capable of generating electric energy in response to various electromagnetic waves projected thereupon and, optionally, at least partially transmitting such waves therethrough. More particularly, the present invention relates to planar arrangements and methods of such photovoltaic systems where photovoltaic members are electrically connected in series without employing any conventional vertical interconnects. Therefore, an exemplary photovoltaic system includes multiple photovoltaic members each of which is arranged to include multiple charge layers, where such members are arranged to be disposed laterally and side by side, where the charge layers of each of the members are arranged to be disposed vertically and contacting each other and to have different polarities arranged in a preset order in order to generate voltage in response to said waves, where at least two of the members are arranged to be disposed adjacent to each other, to generate the voltages in opposite vertical direction, and to be connected in series by their top and/or bottom charge layers in order to enable the system to generate the driving voltage greater than each of the voltages generated by such members. Such a present invention also relates to various methods of providing such photovoltaic system and/or members thereof. In addition, the present invention further relates to various process of providing such photovoltaic systems and/or members thereof.

The present application claims a benefit of a Disclosure Document Number 503,103 which is entitled “Photovoltaic System” and filed on Jan. 3, 2002, an entire portion of which is incorporated herein by reference.

### FIELD OF THE INVENTION

The present invention generally relates to various photovoltaic systems capable of generating electric energy in response to various electromagnetic waves projected thereupon and, optionally, at least partially transmitting such waves therethrough. More particularly, the present invention relates to planar arrangements and methods of such photovoltaic systems where photovoltaic members are electrically connected in series without employing any conventional vertical interconnects. In addition, the present invention relates to various process of providing such photovoltaic systems.

### BACKGROUND OF THE INVENTION

Various photovoltaic (will be abbreviated as “PV” hereinafter) devices of many different types have been in use so as to convert energy of electromagnetic waves into usable electric energy. The PV devices generally include at least one n polarity layer and at least one p polarity layer, where the n and p polarity layers have at least one extra electron and at least one extra hole (i.e., an absence of an electron), respectively. The extra electron of the n polarity layer may move to the p polarity layer, thereby rendering the n polarity layer relatively positive with respect to the p polarity layer upon being irradiated by such waves. The energy conversion results from the PV effect. For example, the solar radiation impinging on the PV device and absorbed by an active region of its semiconductor material such as, e.g., an intrinsic i-layer of amorphous silicon, may generate electron-hole pairs therein. Such electrons and holes may be separated by an electric field between the n and p polarity layers which serve as charge collector layers or simply charge layers, e.g., an electron collector layer or a cathode and a hole collector layer or an anode. Separation of the electrons and holes by the charge collector layers results in generation of electric voltage and flow of electric current. For example, the electrons flow toward the n polarity and/or electron collector layer, while the holes flow toward the p polarity and/or hole collector layer. The electric current flows through an external circuit which connects the n polarity or electron collector layer to the p polarity or hole collector layer as far as the light continues to generate the electron-hole pairs in the PV device.

It is generally desirable to fabricate the PV devices to include a large number of cells. PV cells, e.g., are well known and commonly used for producing a signal for a solid state relay. Such devices generally employ a light emitting diode [LED] which is to b energized by input terminals to irradiate the photosensitive surface of a spaced and insulated PV device. The output of the PV device may serve as the input to a switching device such as a MOS-gated device, typically a power MOSFET or IGBT, which has load terminals that are switched “on” in response to the energization of the LED. The input and output terminals of the relay are isolated by a gap between the LED and the PV device. Such PV devices commonly consist of a large number of series-connected PV cells so as to produce a driving voltage sufficiently high enough to turn on the conventional power switching devices.

Such multiple-cell PV devices may be made in many different ways. One known arrangement employs a stack or pile of PV cells as shown in U.S. Pat. Nos. 4,755,697 and 4,996,577, both issued to Daniel Kinzer. Other PV devices employ a planar array of cells which are junction isolated from one another and are connected in series at their surfaces. Yet other devices are known where individual cells disposed over the surface of a silicon chip may be junction-isolated from one another or may be dielectrically isolated, as shown in U.S. Pat. Nos. 4,227,098 and 4,390,790. The conventional devices, however, have the drawback of high manufacture cost and low manufacturing yields. Alternatively, a planar array of PV cells may be formed in a dielectrically bonded silicon wafer. By this technique, a relatively thick “handle” wafer may be oxide-bonded to, and insulated from a thin device wafer where the junctions are formed, as shown in U.S. Pat. No. 5,549,762 issued to Steven Lizotte.

The prior art PV devices generally insulate a large number of PV cells from one another by a trench structure where the trenches are of a predefined depth and filled with an insulating material to dielectrically insulate each cell. During the fabrication of such a trench structure, however, an oxide or other dielectric material that is grown or deposited in the trench often is thicker at an upper portion of the trench than in a lower region thereof. As a result, the deposited or grown insulating material may pinch off and close an upper opening of the trench while leaving the lower region of the trench unfilled. Such gaps in the trench weaken the insulating properties of the trench and can produce PV devices with lower voltage ratings and poor mechanical properties. This problem is also exacerbated when the trench is etched with the upper part of the walls at a re-entrant angle which may produce a pinch-off region in which the upper opening of the trench is closed off while leaving the lower region in the trench unfilled.

The prior art PV devices with hundreds or thousands of PV cells may also be used to provide electrical power for a variety of applications. For example, interconnection tabs or interconnects may conduct electrical current from one cell to another in series strings, and may also interconnect cells in parallel groups. The interconnects may conventionally be manufactured by punching or etching metal strips or sheets to the desired configuration. Such interconnects are traditionally less than 0.05 mm thick, and are attached to the PV cells using an extremely time consuming manual soldering or welding process or, alternatively, using an elaborate and expensive automated process. In addition to being highly labor intensive, welding or soldering the delicate interconnects to the PV cells is typically a high risk procedure which may result in frequent breakage of the expensive PV cells as well as a high rate of attrition.

Accordingly, it is desirable to produce a PV device that is made of a large number of insulated PV cells which are connected in series so as to produce driving voltage high enough to drive various devices but which are easily manufactured through conventional fabrication techniques or equipment and easily integrated with conventional devices.

### SUMMARY OF THE INVENTION

The present invention generally relates to a planar photovoltaic system which are arranged to generate electric voltage and/or current responsive to electromagnetic waves impinged (or projected) thereupon. More particularly, the present invention relates to planar PV systems and methods thereof where planar charge layers having opposite polarities are arranged laterally and side by side in order to form series connection directly or through a planar lateral contact layer.

A photovoltaic [PV] system refers to any system capable of generating voltage in response to projection of electromagnetic waves thereupon. More particularly, a planar PV system is arranged to extend over a length in a curvilinear lateral direction as well as into a thickness in a curvilinear vertical direction, where such a planar PV system generally has the length greater than the thickness thereof. Each planar PV system includes at least one PV member which in turn may include at least one planar upper charge layer and at least one planar lower charge layer. Such charge layers may extend over layer lengths along the curvilinear lateral direction and into layer thicknesses in the curvilinear vertical direction. The planar PV member may further include at least one planar contact layer which extends over another layer length along the curvilinear lateral direction and into another layer thickness in the curvilinear vertical direction. Most layers of the planar PV member may have the layer lengths greater than the layer thicknesses and may have a first polarity, a second polarity or intrinsic polarity.

In one aspect of this invention, a photovoltaic system is arranged to generate driving voltage in response to electromagnetic waves impinged thereupon. An exemplary photovoltaic system includes multiple photovoltaic members each of which is arranged to include multiple charge layers, where the members are arranged to be disposed laterally and side by side, where the charge layers of each of the members are arranged to be disposed vertically one over the other and contacting each other and to have different polarities arranged in a preset order to generate voltage in response to the waves. In one exemplary embodiment, at least two of the members are arranged to be disposed adjacent to each other and to be connected in series by their top (or bottom) charge layers in order to enable the system to generate the driving voltage greater than each of the voltages generated by such adjacent members. In another exemplary embodiment, at least two of the members are similarly arranged to be disposed adjacent to each other, to be connected by or through their top (or bottom) charge layers, and to generate the voltages in opposite vertical directions in order to enable the system to generate the driving voltage greater than each of the voltages generated by the adjacent members. In another exemplary embodiment, at least two of the members are arranged to be disposed adjacent to each other and to be connected by their top (or bottom) charge layers and where the preset order of the polarities of the charge layers of one of the adjacent members may be arranged to be at least partially opposite to the preset order of the polarities of the charge layers of the other of the adjacent members in order to enable the system to generate the driving voltage greater than each of the voltages which is generated by the adjacent members. In another exemplary embodiment, the foregoing system may include at least one top contact layer and/or at least one bottom contact layer. The top contact layer is arranged to be disposed over and to connect top charge layers of the members disposed adjacent to each other, while the bottom contact layer is arranged to be disposed below and to connect bottom charge layers of such adjacent members. Such top and/or bottom contact layers may be arranged to connect the adjacent members in series in order to enable the system to generate the driving voltage which is greater than each of the voltages generated by the adjacent members. In another exemplary embodiment, top (or bottom) charge layers of the adjacent members are arranged to have different polarities and to be connected to each other to connect the members in series. Alternatively, a top (or bottom) contact layer may be arranged to be disposed over (or below) and to connect top (or bottom) charge layers of such adjacent members to connect such members in series. In the first, second, and fourth embodiments, the charge layers of such adjacent members may be arranged to have orders of the polarities arranged to be at least partially opposite to each other, and such adjacent members may be arranged to be connected in series by or through top (or bottom) charge layers thereof connected to each other and having different polarities. In all of the foregoing embodiments, at least portions of the charge layers of the members may be arranged to be at least partially transparent and/or to have at least one preset focal length in order to provide the system with a transmittivity and/or refractivity to the waves at least one of which is arranged to be at least similar to (or not substantially less than) a transmittivity and/or refractivity to the waves of an at least partially transparent medium over which the members are arranged to be disposed.

In another aspect of this invention, a photovoltaic system is also arranged to generate driving voltage in response to electromagnetic waves impinged thereupon and to transmit at least a portion of the waves therethrough. Such a photovoltaic system includes at least partially transparent multiple photovoltaic members each of which may be arranged to include at least partially transparent multiple charge layers, where the members are arranged to be disposed laterally and side by side, where the charge layers of each of the members are arranged to be disposed vertically one over the other and contacting each other and to have different polarities arranged in a preset order to generate voltage in response to the waves. In one exemplary embodiment, at least two of the members are arranged to be disposed adjacent to each other and to be connected in series by or through their top (or bottom) charge layers in order to enable the system to generate the driving voltage greater than each of the voltages generated by the adjacent members. In another exemplary embodiments, at least two of the members may be arranged to be disposed adjacent to each other, to be connected by or through their top (or bottom) charge layers, and to generate the voltages in opposite vertical directions in order to enable the system to generate the driving voltage which is greater than each of the voltages which is generated by the adjacent members. In another exemplary embodiment, at least two of the members may be arranged to be disposed adjacent to each other and to be connected by or through their top (or bottom) charge layers and where the preset order of the polarities of the charge layers of one of the adjacent members is arranged to be at least partially opposite to the preset order of the polarities of the charge layers of the other of the adjacent members in order to enable the system to generate the driving voltage which is greater than each of the voltages generated by the adjacent members. In another exemplary embodiment, such a photovoltaic system may include at least on top contact layer and/or at least one bottom contact layer both of which are generally arranged to be at least partially transparent. The top contact layer is arranged to be disposed over and to connect top charge layers of two of the members disposed adjacent to each other, while the bottom contact layer is arranged to be disposed below and to connect bottom charge layers of the adjacent members. Such a top and/or bottom contact layer may be arranged to connect such adjacent members in series in order to enable the system to generate the driving voltage which is greater than each of the voltages generated by the adjacent members. In the first three embodiments, top (or bottom) charge layers of such adjacent members may be arranged to have different polarities and to be connected to each other to connect the members in series. In the alternatively, the system may include at least one top (or bottom) contact layer arranged to be disposed over (or below) and to connect top (or bottom) charge layers of such adjacent members to connect the members in series. In the first, second, and fourth embodiments, the charge layers of the adjacent members are arranged to have orders of the polarities arranged to be at least partially opposite to each other, and the adjacent members may be arranged to be connected in series by or through their top (or bottom) charge layers connected to each other and having different polarities. In all of the foregoing embodiments, at least portions of the charge layers of the members are arranged to have at least one preset focal length in order to provide the system with a refractivity to the waves which is arranged to be at least similar to (or not substantially less than) a refractivity to the waves of an at least partially transparent medium over which the members may be disposed.

In another aspect of this invention, a planar photovoltaic system is provided to generate driving voltage in response to electromagnetic waves impinged thereupon. Such a photovoltaic system may be defined across multiple planar layers which are disposed vertically one over the other and contact each other and may include multiple planar photovoltaic members each of which may be arranged to be defined across at least two of such planar layers contacting each other, where the members are arranged to be defined laterally and side by side in different zones of such at least two planar layers and where the planar layers of each of the members are arranged to have different polarities which are arranged in a preset order so as to generate voltage in response to the waves. In one exemplary embodiment, at least two of the members are arranged to be disposed adjacent to each other and to be connected in series by their top (or bottom) planar layers in order to enable the system to generate the driving voltage greater than each of the voltages generated by the adjacent members. In another exemplary embodiment, at least two of such members are arranged to be disposed adjacent to each other, to be coupled by their top (or bottom) planar layers, and to generate the voltages in opposite vertical directions in order to enable the system to generate the driving voltage greater than each of the voltages generated by the adjacent members. In another exemplary embodiments, at least two of the members are arranged to be disposed adjacent to each other and to be connected by their top (or bottom) planar layers and the preset order of the polarities of the planar layers of one of the adjacent members is arranged to be at least partially opposite to the preset order of the polarities of the planar layers of the other adjacent member to enable the system to generate the driving voltage greater than each of the voltages which is generated by the adjacent members. In another exemplary embodiment, the system may further include at least one top contact layer and/or at least one bottom contact layer. The top contact layer is arranged to be defined at least substantially horizontally along at least one of the planar layers which are arranged to be disposed over and to contact top planar layers of two of the members disposed adjacent to each other, and the bottom contact layer is arranged to be defined at least substantially horizontally along at least one of the planar layers which may be arranged to be disposed below and to contact bottom planar layers of the adjacent members. The top and/or bottom contact layers may also be arranged to connect the adjacent members in series in order to enable the system to generate the driving voltage greater than each of the voltages generated by the adjacent members. In all of the above embodiments, at least portions of the planar layers of the members are arranged to be at least partially transparent (and/or to have at least one preset focal length) in order to provide the system with a transmittivity (and refractivity) to the waves arranged to be at least similar to (or not substantially less than) a transmittivity (and refractivity) to the waves of an at least partially transparent medium over which the members are to be disposed. In the first three embodiments, top (or bottom) planar layers of the adjacent members may be arranged to have different polarities and to be connected to each other to connect the members in series. Alternatively, a top (or bottom) contact layer may be arranged to be disposed over (or below) and to connect top (or bottom) planar layers of the adjacent members to connect the members in series. In the first, second, and fourth embodiments, the the planar layers of the adjacent members are arranged to have orders of the polarities arranged to be at least partially opposite to each other, and the adjacent members are arranged to be connected in series by top (or bottom) planar layers thereof which are connected to each other and which have different polarities.

In another aspect of this invention, a planar photovoltaic system is provided to generate driving voltage in response to electromagnetic waves impinged thereupon and to transmit at least a portion of the waves therethrough. The system is defined across multiple planar layers disposed vertically one over the other and contacting each other and may include at least partially transparent multiple planar photovoltaic members each of which may be arranged to be defined across at least two of the planar layers contacting each other, where such members may be arranged to be defined laterally and side by side in different zones of such at least two planar layers, and where the planar layers of each of the members are arranged to be at least partially transparent and to have different polarities arranged in a preset order so as to generate voltage in response to the waves. In one exemplary embodiment, at least two of the members are arranged to be disposed adjacent to each other and to be connected in series by or through their top (or bottom) planar layers in order to enable the system to generate the driving voltage which is greater than each of the voltages generated by the above adjacent members. In another exemplary embodiment, at least two of the members are arranged to be disposed adjacent to each other, to be connected by ot through their top (or bottom) planar layers, and to generate the voltages in opposite vertical directions to enable the system to generate the driving voltage greater than each of the voltages generated by the adjacent members. In another exemplary embodiment, at least two of the members are arranged to be disposed adjacent to each other and to be connected by or through their top (or bottom) planar layers and the preset order of the polarities of the planar layers of one of the adjacent members is arranged to be at least partially opposite to the preset order of the polarities of the planar layers of the other of the adjacent members in order to enable the system to generate the driving voltage greater than each of the voltages generated by the members. In another exemplary embodiment, the system further includes at least one top contact layer and/or at least one bottom contact layer both of which are arranged to be at least partially transparent. The top contact layer is defined at least substantially horizontally along at least one of the planar layers arranged to be disposed over and to contact top planar layers of two of such members disposed adjacent to each other, while the bottom contact layer is defined at least substantially horizontally along at least one of the planar layers disposed below and to connect bottom planar layers of the adjacent members. The the top and/or bottom contact layers may be arranged to connect the adjacent members in series in order to enable the system to generate the driving voltage which is greater than each of the voltages generated by the adjacent members. In all of the above embodiments, at least portions of the planar layers of the members may be arranged to have at least one preset focal length in order to provide the system with a refractivity to the waves arranged to be at least similar to or not substantially less than a refractivity to the waves of an at least partially transparent medium over which the members are arranged to be disposed. In the first three embodiments, top (or bottom) planar layers of the adjacent members are arranged to have different polarities and to be connected to each other to connect the members in series. Alternatively, a top (or bottom) contact layer is arranged to be disposed over (or below) and to connect top (or bottom) planar layers of the adjacent members to connect the members in series. In the first, second, and fourth embodiments, the planar layers of the adjacent members are arranged to have orders of the polarities arranged to be at least partially opposite to each other, and the adjacent members are arranged to be connected in series by top (or bottom) planar layers thereof connected to each other and having different polarities.

In another aspect of this invention, a photovoltaic system may be provided to generate driving voltage in response to electromagnetic waves impinged thereupon. Such a system includes multiple photovoltaic members such as, e.g., a first photovoltaic member and a second photovoltaic member. The first member may include multiple first charge layers which are arranged to be disposed vertically one over the other and contacting each other and to have different polarities arranged in a first order to generate first voltage in response to the waves. The second photovoltaic member includes multiple second charge layers which are arranged to be disposed vertically one over the other and contacting each other, to be disposed laterally and adjacent to the first charge layers of the first member, and to have different polarities arranged in a second order to generate second voltage in response to the waves in one exemplary embodiment, the first and second members are arranged to be connected in series by or through their top (or bottom) charge layers in order to enable the system to generate the driving voltage greater than each of the first and second voltages. In another exemplary embodiment, the first and second members may be arranged to be connected by or through their top (or bottom) charge layers and to generate the first and second voltages in opposite vertical directions in order to enable the system to generate the driving voltage greater than each of the first and second voltages. In another exemplary embodiment, the first and second members may be arranged to be connected by or through their top (or bottom) charge layers, while the first and second orders of the polarities may be arranged to be at least partially opposite to each other so as to enable the system to generate the driving voltage greater than each of the first and second voltages. In another exemplary embodiment, the system may further include at least one top contact layer and/or at least one bottom contact layer. The top contact layer may be arranged to be disposed over and to connect top charge layers of the first and second members, whereas the bottom contact layer is arranged to be disposed below and to connect bottom charge layers of the first and second members, where the top and/or bottom contact layers may be arranged to connect the first and second members in series so as to enable the system to generate the driving voltage greater than each of the first and second voltages. In all of the above embodiments, at least portions of the charge layers of the first and second members may be arranged to be at least partially transparent (and to have at least one preset focal length) in order to provide the system with a transmittivity and/or refractivity to the waves arranged to be at least similar to (or not substantially less than) a transmittivity and/or refractivity to the waves of at least partially transparent medium over which the first and second members are to be disposed. In the first three embodiments, top (or bottom) charge layers of the first and second members may also be arranged to have different polarities and to be connected to each other to connect the members in series. Alternatively, a top (or bottom) contact layer may be arranged to be disposed over (or below) and to connect top (or bottom) charge layers of the first and second members to connect the members in series. In the first, second, and fourth embodiments, the charge layers of the first and second members may be arranged to have orders of the polarities which are arranged to be at least partially opposite to each other, and the first and second members may be arranged to be connected in series by or through top (or bottom) charge layers thereof connected to each other and having different polarities.

In another aspect of this invention, a photovoltaic system may be provided to generate driving voltage in response to electromagnetic waves impinged thereupon and transmitting at least a portion of the waves therethrough. Such a system may include a first photovoltaic member and a second photovoltaic member. The first member is configured to be at least partially transparent and to include at least partially transparent multiple first charge layers which are arranged to be disposed vertically one over the other and contacting each other and to have different polarities arranged in a first order to generate first voltage in response to the waves, and a second member is configured to be at least partially transparent and to include at least partially transparent multiple second charge layers which are arranged to be disposed vertically one over the other and contacting each other, to be disposed laterally and adjacent to the first charge layers, and to have different polarities arranged in a second order to generate second voltage in response to the waves. In one exemplary embodiment, the first and second members may be arranged to be connected in series by or through their top (or bottom) charge layers in order to enable the system to generate the driving voltage which is greater than the first and/or second voltages. In another exemplary embodiment, the first and second members may be arranged to be connected by or through their top (or bottom) charge layers and to generate the first and second voltages in opposite vertical directions so as to enable the system to generate the driving voltage greater than the first and/or second voltages. In another exemplary embodiment, the first and second members are arranged to be connected by their top (or bottom) charge layers and where the first and second orders of the polarities are arranged to be at least partially opposite to each other in order to enable the system to generate the driving voltage greater than the first and/or second voltages. In another exemplary embodiment, the system may further include at least one top contact layer and/or at least one bottom contact layer both of which may be arranged to be at least partially transparent. The top contact layer may be arranged to be disposed over and to connect top charge layers of the first and second members, while the bottom contact layer may be arranged to be disposed below and to connect bottom charge layers of the first and second members. Either of the top and bottom contact layers may be arranged to connect the first and second members in series in order to enable the system to generate the driving voltage which may be greater than the first and/or second voltages. In all of the above embodiments, at least portions of the charge layers of the first and second members may be arranged to have at least one preset focal length in order to provide the system with a refractivity to the waves arranged to be at least similar to or not substantially less than a refractivity to the waves of at least partially transparent media over which the the first and second members are arranged to be disposed. In the first three embodiments, top (or bottom) charge layers of the first and second members may be arranged to have different polarities and to be connected to each other to connect the members in series. In the alternative, a top (or bottom) contact layer may be arranged to be disposed over (or below) and to connect top (or bottom) charge layers of the the first and second members to connect the members in series. In the first, second, and fourth embodiments, the charge layers of the the first and second members may further be arranged to have orders of the polarities arranged to be at least partially opposite to each other and the the first and second members may be arranged to be connected in series by their top (or bottom) charge layers connected to each other and having different polarities.

In another aspect of this invention, a planar photovoltaic system may be provided to generate driving voltage in response to electromagnetic waves impinged thereupon. The system may include multiple photovoltaic members defined across multiple planar layers disposed vertically one over the other and contacting each other. For example, the system may include a first photovoltaic member and a second photovoltaic member. The first member may be arranged to be defined vertically across a first zone of at least two of the planar layers contacting each other, where the planar layers of the first member are arranged to have different polarities arranged in a first order to generate first voltage in response to the waves. The second member may also be arranged to be defined vertically across a second zone of the at least two of the planar layers contacting each other and to be also defined laterally adjacent to the first member, where the planar layers of the second member are arranged to have different polarities arranged in a second order to generate second voltage in response to the waves. In one exemplary embodiment, the first and second members are arranged to be connected in series by or through their top (or bottom) planar layers in order to enable the system to generate the driving voltage greater than the first and/or second voltages. In another exemplary embodiment, the first and second members are arranged to be coupled by or through their top (or bottom) planar layers and to generate the voltages in opposite vertical directions in order to enable the system to generate the driving voltage which is greater than each of the first and second voltages. In another exemplary embodiment, the first and second members may be arranged to be connected by or through their top (or bottom) planar layers, and the first and second orders of the polarities may also be arranged to be at least partially opposite to each other in order to enable the system to generate the driving voltage greater than the first and/or second voltages. In another exemplary embodiment, the system may also include at least one top contact layer and at least one bottom contact layer. The top contact layer is defined at least substantially horizontally along at least one of the planar layers which are arranged to be disposed over and to contact top planar layers of the first and second members, while the bottom contact layer may be defined at least substantially horizontally along at least one of the planar layers which are arranged to be disposed below and to contact bottom planar layers of the first and second members. The top and/or bottom contact layers may also be arranged to connect the first and second members in series in order to enable the system to generate the driving voltage greater than the first and/or second voltages. In all of the above embodiments, at least portions of the planar layers of the first and second members may be arranged to be at least partially transparent and/or to have at least one preset focal length in order to provide the system with a transmittivity and/or refractivity to such waves which may be arranged to be at least similar to (or not substantially less than) a transmittivity and/or refractivity to the waves of at least partially transparent media over which the members may be arranged to be disposed. In the first three embodiments, top (or bottom) planar layers of the first and second members may be arranged to have different polarities and to be connected to each other to connect the members in series. In the alternative, a top (or bottom) contact layer may be arranged to be disposed over (or below) and to connect top (or bottom) planar layers of the first and second members to connect the members in series. In the first, second, and fourth embodiments, the planar layers of the first and second members may be arranged to have orders of the polarities arranged to be at least partially opposite to each other, whereas the first and second members may be arranged to be connected in series by top (or bottom) planar layers thereof connected to each other and having different polarities.

In another aspect of this invention, a planar photovoltaic system may generate driving voltage in response to electromagnetic waves impinged thereupon and also to transmit at least a portion of the waves therethrough. The system may include multiple photovoltaic members and be defined across multiple planar layers disposed vertically one over the other and contacting each other. For example, the system includes a first photovoltaic member and a second photovoltaic member. The first member may be arranged to be at least partially transparent and to be defined vertically across a first zone of at least two of the planar layers contacting each other, in which the planar layers of the first member may be arranged to be at least partially transparent and to have different polarities arranged in a first order to generate first voltage in response to the waves. The second member may be arranged to be at least partially transparent and to be defined vertically across a second zone of such at least two of the planar layers contacting each other and to be also defined laterally adjacent to the first member, where the planar layers of the second member are arranged to be at least partially transparent and to have different polarities arranged in a second order so as to generate second voltage in response to the waves. In one exemplary embodiment, the first and second members may be connected in series by or through their top (or bottom) planar layers in order to enable the system to generate the driving voltage greater than the first and/or second voltages. In another exemplary embodiment, the first and second members may be arranged to be coupled by or through their top (or bottom) planar layers and to generate the voltages in opposite vertical directions in order to enable the system to generate the driving voltage greater than the first and/or second voltages. In another exemplary embodiment, the first and second members may be arranged to be connected by or through their top (or bottom) planar layers, and the first and second orders of the polarities may further be arranged to be at least partially opposite to each other in order to enable the system to generate the driving voltage greater than the first and/or second voltages. In another exemplary embodiment, the system may include at least one top contact layer and at least one bottom contact layer both of which may be arranged to be at least partially transparent. The top contact layer is arranged to be defined at least substantially horizontally along at least one of the planar layers arranged to be disposed over and to contact top planar layers of the first and second members, whereas the bottom contact layer may be arranged to be defined at least substantially horizontally along at least one of the planar layers arranged to be disposed below and to contact bottom planar layers of the first and second members. The top and/or bottom contact layers may be arranged to connect the first and second members so as order to enable the system to generate the driving voltage greater than each of the first and second voltages. In all of the above embodiments, at least portions of the planar layers of the first and second members may be arranged to have at least one preset focal length in order to provide the system with a refractivity to the waves arranged to be at least similar to (or not substantially less than) a refractivity to the waves of at least partially transparent media on which the first and second members may be arranged to be disposed. In the first three embodiments, top (or bottom) planar layers of the first and second members may be arranged to have different polarities and to be connected to each other to connect the members in series. Alternatively, a top (or bottom) contact layer may be arranged to be disposed over (or below) and to connect top (or bottom) planar layers of the first and second members in order to connect the members in series. In the first, second, and fourth embodiments, such planar layers of the first and second members may be arranged to have orders of such polarities arranged to be at least partially opposite to each other, and the first and second members may be arranged to be connected in series by or through their top (or bottom) planar layers which are connected to each other and which have different polarities.

Following embodiments may also apply to all aspects and/or embodiments of such photovoltaic systems and/or members of the present invention which have been described hereinabove and which will be described hereinafter.

Various photovoltaic members and/or contact layers of the photovoltaic system may be made of rigid and/or flexible materials so as to allow their deformation. The top and/or bottom contact layers may be arranged to extend preset lengths which are shorter than heights of at least some or all of the members. More particularly, the top and/or bottom contact layers may be arranged to not traverse any of the foregoing charge layers, planar layers, and/or members. The system may include at least one switch arranged to operate between an on-state and an off-state, where the switch is arranged to connect the system to an article over which the system is disposed in the on-state and to disconnect the system from the article in the off-state. Such a switch may be arranged to move from one to the other of such states in response to the waves.

The photovoltaic members may be arranged to be connected to each other by a series and/or parallel connection and to generate voltages independently of each other such that the system may be arranged to generate the driving voltage when at least one of the members may be disconnected from others members. Each member may be arranged to include at least substantially similar number of the charge (or planar) layers and, therefore, to have an at least substantially similar transmittivity (and/or refractivity) to the waves. Accordingly, the system may be arranged to have the transmittivity (and/or refractivity) which is at least substantially uniform through its horizontal length, e.g., compared with a transmittivity (and/or a refractivity) of another photovoltaic system in which multiple members may be disposed next to each other and connected in series by multiple contact layers vertically traversing such members. At least a substantial number of such members may be arranged as multiple member groups, and a preset number of the members may be arranged to be connected in series in each of such member groups in order to generate the driving voltage. In addition, the member groups may be arranged to be connected in parallel so that the system may generate the driving voltage even when at least a non-negligible number of the members may be disabled or disconnected.

In another aspect of this invention, a photovoltaic sheet may be provided to generate multiple driving voltages with different amplitudes in response to electromagnetic waves impinged thereupon. Such a sheet may include a support and at least one photovoltaic system which may be arranged to be, embedded into, fixedly disposed over, movably disposed over, and/or detachably disposed over at least one side of the support. Such a photovoltaic system may be arranged according to any of the above embodiments described herein and to supply the driving voltage to the support and/or an article over (or on) which such a support may be disposed. In one exemplary embodiment, the support may include an adhesive layer to enable detachable and/or fixed coupling of the system onto an article. In another exemplary embodiment, the support and system may be arranged to be elastic/deformable. In another exemplary embodiment, the support may include at least one member portion and at least one connection portion, while the system may include at least one connector which is arranged to provide the members with a series and/or parallel connection therebetween. The members may be disposed in the member portion of the support, while the connector may be disposed in the connection portion thereof, while the connection portion and connector may be arranged to be at least partially elastic or deformable in order to allow at least partial deformation thereof.

In another aspect of this invention, a photovoltaic lens for eye glasses may be provided. Such a lens may include a lens and at least one photovoltaic system. Such a lens may be arranged to be at least partially transparent, to transmit at least a portion of electromagnetic waves therethrough, and to define a transmittivity and/or refractivity at least one of which may be arranged to change by driving voltage. The system is arranged to be at least partially transparent and to be embedded into, fixedly disposed on, movably disposed over, and/or detachably disposed over the lens. Such a system may be provided according to any of the embodiments described herein and arranged to supply the driving voltage to the lens in order to vary the transmittivity and/or refractivity of the lens.

In another aspect of this invention, a photovoltaic glass may be provided to include a sheet of glass and at least one photovoltaic system. The glass sheet may be arranged to be at least partially transparent, to transmit at least a portion of electromagnetic waves therethrough, and to also define a transmittivity and/or refractivity to electromagnetic waves at least one of which may be arranged to be varied by driving voltage. The system may also be provided according to any of the embodiments described herein and arranged to supply the driving voltage to the sheet of glass in order to vary the transmittivity and refractivity of the sheet.

In another aspect of the present invention, an electro-optic device may be provided to include at least one electro-optic system and at least one photovoltaic system. The electro-optic system may be arranged to change at least one of its optical properties in response to driving voltage, while the photovoltaic system may be arranged to be at least partially transparent and embedded into, movably disposed over, fixedly disposed on, detachably disposed over, and/or operatively coupled to such an electro-optic system. The photovoltaic system may be provided according to any of the embodiments described herein and arranged to supply the driving voltage to the electro-optic system so as to vary or change the optical properties of the electro-optic system.

Following embodiments may also apply to all aspects and/or embodiments of such photovoltaic sheet, photovoltaic lens, photovoltaic glass, and/or electro-optic devices of this invention which have been described hereinabove and which will be described hereinafter. The photovoltaic lens or glass may be arranged to receive the driving voltage from the system or an external energy source. The members may be arranged to be connected to each other by series and/or parallel connection and to generate the voltages independently of each other so that the system may be arranged to generate the driving voltages when at least a portion of the support, lens, and/or glass including the members disposed thereover are removed therefrom. The system may be arranged to cover only a portion of the lens or glass. In the alternative, the system may be arranged to cover only a portion of the lens or glass, while the rest of the lens or glass may be arranged to be covered by another material arranged to have a transmittivity and/or refractivity at least substantially similar to that of the system.

In another aspect of this invention, a photovoltaic system may be provided to generate driving voltage in response to electromagnetic waves projected thereupon and arranged to extend along its length in a curvilinear lateral direction and to extend into a thickness in a curvilinear vertical direction. Such a system includes multiple members each of which has at least one upper charge layer and at least one lower charge layer, where each charge layer is arranged to extend along a layer length in the curvilinear lateral direction and to extend into a layer thickness in the curvilinear vertical direction. Such a system may include a first member and a second member, where the first member includes at least one first upper charge layer which has a first polarity and at least one first lower charge layer which has a second polarity and where at least a portion of the first upper charge layer is arranged to be disposed over at least a portion of the first lower charge layer. The second member includes at least one second upper charge layer which has the second polarity and at least one second lower charge layer which has the first polarity. Such a second member is arranged to be disposed laterally adjacent to the first member and at least a portion of the second upper charge layer is arranged to be disposed over at least a portion of the second lower charge layer. In one embodiment, the first and second upper charge layers may be arranged to be connected to each other in order to connect the first and second members in series. Alternatively, the first and second lower charge layers may be arranged to be connected to each other in order to connect the first and second members in series. In another embodiment, at least one contact layer may be arranged to extend substantially along the lateral direction and to be disposed over (or below) and to connect at least portions of the first and second upper (or lower) charge layers having different polarities. Alternatively, at least one contact layer may be arranged to extend horizontally, to not vertically traverse any layer thickness of any of the first and second charge layers, and to connect at least portions of the first and second upper (or lower) charge layers having different polarities.

In another embodiment, the system includes a first member and a second member, where the first member includes at least one first upper charge layer having a first polarity and at least one first lower charge layer having a second polarity, where at least a portion of the first upper charge layer may be arranged to be disposed over at least a portion of the first lower charge layer. The second member includes at least one second upper charge layer having the second polarity and at least one second lower charge layer having the first polarity. Such a second member is disposed adjacent to the first member at least substantially along the lateral direction, and at least a portion of the second upper charge layer is arranged to be disposed over at least a portion of such a second lower charge layer. In one embodiment, the first and second upper charge layers may be arranged to be disposed horizontally at a same level and to be connected to each other in order to connect the first and second members in series. In the alternative, the first and second lower charge layers may be arranged to be disposed horizontally at a same level and to be connected to each other in order to connect the first and second members in series. In another embodiment, at least one contact layer may be arranged to extend substantially along the lateral direction and to be disposed over (or below) and to connect at least portions of the first and second upper (or lower) charge layers having different polarities. In the alternative, at least one contact layer may be arranged to extend horizontally, to not vertically traverse any layer thickness of any of the first and second charge layers, and to connect at least portions of the first and second upper (or lower) charge layers having different polarities.

In another embodiment, the system may include a first member, a second member, and a third member. The first member includes at least one first upper charge layer having a first polarity and at least one first lower charge layer having a second polarity, where at least a portion of the first upper charge layer is arranged to be disposed over at least a portion of the first lower charge layer. The second member includes at least one second upper charge layer having the first polarity and at least one second lower charge layer having the second polarity, where at least a portion of such a second upper charge layer is disposed over at least a portion of the second lower charge layer. The third member includes at least one third upper charge layer having the second polarity and at least one third lower charge layer having the first polarity and disposed between the first and second members. At least a portion of the third upper charge layer may be arranged to be disposed over at least a portion of the third lower charge layer. In on embodiment, the system includes a first contact layer and a second contact layer, where the first contact layer may be arranged to extend substantially along the lateral direction and to be disposed over and to connect the first and third upper charge layers, while the second contact layer may be arranged to extend substantially along the lateral direction and to be disposed below and to connect the third and second lower charge layer. In another embodiment, the first contact layer is arranged to not vertically traverse any layer thickness of any of the first, second, and third charge layers and to be disposed below and to connect the first and third lower charge layers. The second contact layer may be arranged to not vertically traverse any layer thicknesses of any of the first, second, and third charge layers and to be disposed over and to connect the third and second upper charge layers.

In another generalized embodiment, the system may include M photovoltaic members, where N of the M members are disposed adjacent to one another substantially along the lateral direction where M and N are both integers and M>N>1. A j-th member of the N members may be arranged to include at least one j-th upper charge layer and at least one j-th lower charge layer where j is another integer between 1 and N. At least a portion of the j-th upper charge layer may also be disposed over at least a portion of the j-th lower charge layer substantially along the vertical direction, whereas at least N−1 contact layers may be arranged to extend substantially along the lateral direction. Each of the contact layers may be arranged to have lengths greater than heights thereof, where a k-th contact layer may be disposed over at least portions of a k-th upper charge layer which has a first polarity and a (k+1)th upper charge layer which has a second polarity in order to connect the k-th and (k+1)th upper charge layers when k is an odd integer and N−1>k>1, and where a k-th contact layer may also be disposed below at least portions of a k-th lower charge layer which has the second polarity and below at least portions of a (k+1)th lower charge layer which has the first polarity in order to connect the k-th and (k+1)th lower charge layers when k is an even integer.

The photovoltaic systems and/or members thereof described heretofore and to be described herein after may be provided according to following embodiments.

The above contact layers may be arranged to not vertically traverse any thickness of the first and/or second charge layers. The system may be arranged to have the length which may be greater than the thickness thereof. At least a substantial number of the charge layers of the first and second members may be arranged to extend along the layer lengths which are typically greater than the layer thicknesses. The first and second upper (and/or lower) charge layers may be disposed adjacent to each other substantially along the lateral direction. The first and second upper (and/or lower) charge layers may also be arranged to be disposed laterally side by side and adjacent to each other. At least portions of the first and second upper (and/or lower) charge layer may be arranged to be connected to each other. At least portions of the first and second upper (and/or lower) charge layers may also be disposed adjacent to and to contact each other along the lateral direction, and the first and second upper (and/or lower) charge layers may be arranged to have the layer thicknesses substantially less than the layer lengths, thereby minimizing electric current between the first and second upper charge layers. The system may also include at least one dielectric layer disposed between at least portions of the first and second upper (and/or lower) charge layers to provide insulation therebetween. The first and second polarities may be respectively an n and a p conductivity type or, alternatively, a p and an n conductivity type. Such charge layers of the first (or second) polarity may be electron collector layers, whereas the charge layers of the second (or first) polarity may be hole collector layers. The first and second upper (and/or lower) charge layers and/or various contact layers may be arranged to be made of substances which are at least partially transparent. The first member may have at least one first intermediate layer which is arranged to be disposed between the first and second upper (or lower) charge layers, to extend substantially along the lateral direction, and to generate electron-hole pairs in response to the waves. The first intermediate layer may arranged to be made of (or include) semiconductive material and/or to be made of at least partially transparent substances. The second member may include at least one second intermediate layer disposed between the second upper and lower charge layers, to extend substantially along the lateral direction, and to generate electron-hole pairs in response to the waves. The second first intermediate layer may also be arranged to be made of (or include) semiconductive material and/or to be made of at least partially transparent material. The charge layers of the member may be arranged to be made of material such that a composite vertical refractive index of the system obtained along a vertical line across a thickness of the system may be at least substantially similar along the lateral direction. Such a system may further include at least one refraction layer disposed over one of the members along the vertical direction such that a composite vertical refractive index of the system obtained along a vertical line across a thickness of the system may be at least substantially similar along the lateral direction. The system may include at least one refraction layer disposed below one of the members along the vertical direction so that a composite vertical refractive index of the system obtained along a vertical line across a thickness of the system may be at least substantially similar along the lateral direction. At least one of the member may also be arranged to include at least two additional charge layers between its upper and lower charge layers, and the additional charge layers may be arranged substantially along the vertical direction in a preset order of alternating polarities in order to form multiple vertically arranged members along the vertical direction. At least one of the charge layers of at least one of the members may be arranged to form an area capable of being soldered.

In another aspect of the present invention, a method may be provided for connecting multiple photovoltaic members of a photovoltaic system in series. In one embodiment, the method may include the steps of disposing multiple charge layers vertically one over the other in each of the members, disposing two photovoltaic members laterally side by side and adjacent to each other, arranging the charge layers of one of the members in a first order of polarities, and arranging the charge layers of the other of the members in a second order of the polarities arranged to be at least partially opposite to the first order of the polarities. In one example, the method may include the step of connecting the members in series by connecting top charge layers of the members. In another example, the method may include the step of connecting the members in series by connecting bottom charge layers of the members. In another embodiment, the method includes the steps of disposing multiple charge layers vertically one over the other for each of the members, disposing two photovoltaic members laterally side by side and adjacent to each other, arranging the charge layers of one of the members in a first order of polarities, and arranging the charge layers of the other of the members in a second order of the polarities arranged to be at least partially opposite to the first order of the polarities. For example, the method includes the step of connecting the members in series by providing a contact layer over top charge layers of the members having different polarities. In another example, the method includes the step of connecting the members in series by providing a contact layer below bottom charge layers of the members having different polarities.

In another aspect of this invention, a method may be provided for a photovoltaic system having a horizontal length which is greater than a vertical height thereof, having at least substantially uniform transmittivity (and/or refractivity) along its length to electromagnetic waves, and also including multiple photovoltaic members which are arranged to be connected to each other in series and each of which is arranged to include multiple charge layers. In one embodiment, the method may include the steps of disposing multiple charge layers vertically one over the other in one of such members, arranging such charge layers of one of the members to have one order of polarities, disposing multiple charge layers vertically one over the other in another of the members, arranging the charge layers of the another member to have another order of polarities which may be arranged to be at least partially opposite to the one order, and disposing the one and another members laterally side by side and adjacent to each other. In one example, such a method may include the step of connecting the members in series by connecting top charge layers of the members. In another example, the method may include the step of connecting the members in series by connecting bottom charge layers of the members. In yet another example, the method includes the step of disposing a horizontal contact layer over at least substantial portions of top (or bottom) charge layers of the one and another members so as to connect the top (or bottom) layers of one and another members, thereby arranging the transmittivity (and/or refractivity) of the members to be at least substantially uniform along the length of such a system while providing serial connection between the one and another members. In another example, the method includes the step of disposing a horizontal contact layer over at least portions of top (or bottom) charge layers of the one and another members so as to connect the top (or bottom) layers of the one and another members and disposing a horizontal filler layer over other portions of the top (bottom) charge layers of the members, thereby arranging the transmittivity (and/or refractivity) of the members to be at least substantially uniform along the length of the system while providing serial connection between the one and another members.

In another embodiment, the method may include the steps of disposing at least one first upper charge layer of a first member, where the first upper charge layer may have a first polarity and may be arranged to extend substantially along the lateral direction, and then disposing at least one second upper charge layer of a second member adjacent to the first upper charge layer, where the second upper charge layer may have a second polarity and may be arranged to extend substantially along the lateral direction. In one example, the method includes the step of connecting the members in series by connecting top charge layers of the members. In another example, the method includes the step of connecting the members in series by connecting bottom charge layers of the members. In yet another example, the method includes the step of disposing at least one contact layer extending substantially along the lateral direction and arranged to be disposed over and to connect at least portions of the first and second upper charge layers. In another example, the method includes the step of disposing at least one contact layer arranged to not vertically traverse any layer thickness of any of the first and second charge layers and to be disposed over and to connect at least portions of the first and second upper charge layers.

In another embodiment, the method may include the steps of disposing at least one first lower charge layer having a second polarity, disposing at least one second lower charge layer having a first polarity adjacent to the first lower charge layer along the lateral direction, disposing at least a portion of at least one first upper charge layer having the first polarity on at least a portion of the first lower charge layer along the vertical direction, and disposing at least a portion of at least one second upper charge layer having the second polarity on at least a portion of the second lower charge layer along the vertical direction. In one example, the method may include the step of connecting the members in series by connecting top charge layers of the members. In another example, the method may include the step of connecting the members in series by connecting bottom charge layers of the members. In another example, the method includes the step of disposing at least one contact layer which may be arranged to extend substantially along the lateral direction and to be disposed over at least portions of the first and second upper charge layers so as to connect the first and second upper charge layers. In another example, the method includes the step of disposing at least one contact layer in a direction not vertically traversing any layer thickness of any of the first and second charge layers, where the contact layer may be disposed over at least portions of the first and second upper charge layers in order to connect the first and second upper charge layers.

In another aspect of the present invention, a method may be provided for connecting multiple planar photovoltaic members of a photovoltaic system in series without employing vertically traversing contact layers. In one embodiment, the method may include the steps of depositing a first planar layer, doping a first region of such a first planar layer into a first polarity of a first order of polarities, doping a second region of the first planar layer into a first polarity of a second order of the polarities, where such a second order may be arranged to be at least partially opposite to the first order, depositing a second planar layer over the first planar layer, doping a first region of the second planar layer which may be arranged to at least partially overlap with the first region of the first planar layer into a second polarity of the first order, doping a second region of the second planar layer which may be arranged to at least partially overlap with the second region of the first planar layer into a second polarity of the second order, and repeating the depositing and doping until the regions of the planar layers including the first region may be arranged to form a first member completing the first order and until the regions of the planar layers including the second region are arranged to form a second member completing the second order. In one example, the method may include the step of connecting top planar layers of the members, thereby connecting the members in series. In another example, the method may include the step of connecting bottom planar layers of the members, thereby connecting the members in series. In another example, the method includes the step of providing a contact layer over top charge layers of the members, thereby connecting the members in series. In yet another example, the method may include the step of providing a contact layer below bottom charge layers of such members, thereby connecting the members in series.

Various methods for providing such photovoltaic systems and/or members thereof described heretofore and to be described herein after may include one or more of the following steps. Such a step may be arranging the system to be at least partially transparent, thereby providing such a system with preset transmittivity (and/or refractivity) to the waves. The step may be arranging the members and/or contact layers to be made of (or include) rigid and/or flexible materials, thereby allowing such members and/or contact layers to deform to at least some extent. The step may be extending the top contact layers over preset lengths less than heights of the members and/or may be not traversing the contact layers across any of the charge (or planar) layers (or members). Such steps may further be connecting the members to each other by series and/or parallel connections, and then generating the voltages independently of each other, thereby generating the driving voltages when one or more of the members may be damaged and/or disconnected from others of the members. The step may also be including in each of such members at least a substantially similar or identical number of the charge (or planar) layers, thereby arranging the members to have at least substantially similar transmittivity (and/or refractivity) to the waves arranged to be at least substantially uniform through its horizontal length. The step may be covering at least substantial areas of the top and/or bottom planar layers by the top and/or bottom contact layer, thereby keeping transmittivity (and/or refractivity) of the system and/or their members to the waves at least substantially uniform along a length of the system and/or the members. The steps may be grouping at least a substantial number of such members into multiple member groups, connecting a preset number of the members in series in each of the member groups to generate the driving voltage, and connecting the member groups in parallel, thereby generating the driving voltage even when at least a non-negligible number of the members may be disabled. Such a step may also be insulating at least a portion between the first and second upper charge layers. The method may further include the step of manipulating optical property of the system by composing the first and second upper charge layers and contact layer with materials capable of providing composite vertical refractive indices along a vertical line across a thickness of the system which is arranged to be at least substantially similar along the lateral direction. The method may further include the step of providing at least one refraction layer also made of material capable of manipulating composite vertical refractive indices along a vertical line across a thickness of the system which may be arranged to be at least substantially similar along the lateral direction. Such a method may further include the step of providing at least two extra charge layers between the upper and lower charge layers by arranging the extra charge layers to be substantially along the vertical direction in an alternating order polarities in order to form multiple vertically arranged members along the vertical direction. The step may also be providing at least one of the charge layers with an area capable of being soldered.

In another aspect of this invention, a method may be provided for a photovoltaic sheet capable of generating multiple amplitudes of driving voltages in response to electromagnetic waves impinged thereupon. The method may include the steps of disposing a support, providing a photovoltaic system by at least one of the steps and/or aspects of the methods this invention and/or according to various aspects and/or embodiments of the systems of this invention, disposing the system over at least one side of the support, supplying the driving voltage to the support or an article over which the support is disposed. In one embodiment, the method may include the steps of disposing a layer of adhesive on the other side of the support and attaching the support onto another article. In another embodiment, the method includes the step of arranging the support and/or photovoltaic system to be elastic and/or deformable.

In another aspect of this invention, a method may be provided for a photovoltaic lens for eye glasses. The method may include the steps of arranging a lens to be at least partially transparent, to transmit the waves therethrough, and to define its transmittivity and refractivity at least one of which may be arranged to be varied by driving voltage, providing a photovoltaic system according to at least one of the steps and/or aspects of the methods of this invention and/or according to various aspects and/or embodiments of the system of this invention, disposing the photovoltaic system over at least one side of the lens, supplying the driving voltage to the lens in order to vary the transmittivity and/or refractivity of the lens.

In another aspect of this invention, a method may be provided for a photovoltaic glass. Such a method includes the steps of arranging a sheet of glass to be at least partially transparent, to transmit therethrough the waves, and to define a transmittivity and/or refractivity at least one of which may be arranged to be varied by driving voltage, providing a photovoltaic system according to at least one of the steps and/or aspects of the methods of this invention and/or according to various aspects and/or embodiments of the system of this invention, disposing the photovoltaic system over at least one side of the lens, and then supplying the driving voltage to the glass in order to vary the transmittivity and/or refractivity of the lens.

In another aspect of the present invention, various processes may also be arranged to provide various photovoltaic systems and/or their members which may be employed for various purposes as described heretofore and to be described hereinafter. Such systems and/or members are provided by any process which includes any of the foregoing steps of various aspects of the methods of this invention as described heretofore and to be described hereinafter.

As used herein, the term “photovoltaic system,” “PV system,” and/or simply “system” generally refer to any system with one or more “photovoltaic members,” “PV members” and/or “members” each of which may be capable of creating “photovoltaic effects” or “PV effects” thereby. Such a member may include at least one p-n junction, at least one p-i-n junction, at least one Schottky junction, and/or other junctions capable of generating electric voltage when irradiated by electromagnetic waves with a preset range of wavelengths. Such a system and/or member may be preferably arranged to have a planar shape, but may also be fabricated to have a curved shape in order to form a curvilinear two-dimensional and/or three-dimensional article.

A “curvilinear direction” generally refers to a two-or three-dimensional direction along an axis which may be curved and/or linear. The propositions “along” and “in” may be interchange ably used in conjunction with the “curvilinear direction.”

The term “lateral direction” generally means a direction along a horizontal and long axis of the photovoltaic system, whereas the term “vertical direction” usually refers to a direction along a vertical and short axis of the photovoltaic system.

The term “conductive” generally means a property of a material allowing passage of electrons and/or holes therethrough. A “conductive material” is a material with a r sistivity less than 10⁻² ohm-cm, and is generally inclusive of “semiconductive material” of which the resistivity is between 10⁻² and 10⁵ to 10¹⁰ ohm-cm, where the conductivity is defined as a resistance multiplied by a cross-sectional area divided by a length.

A material having an “n polarity,” “n conductivity type” or simply “n type” generally refers to a conductive material and, more particularly, a semiconductive material having at least one extra or free electron. A material having a “p polarity,” “p conductivity type” or simply “p type” generally refers to a conductive material and, more particularly, a semiconductive materials at least one hole (i.e., absence of an electron). An n or p type charge layer may be made of or include materials intrinsically having at least one extra electron or hole or may be made of or include materials doped by n or p type dopants.

A “charge layer” is a layer made of or include at least one material capable of attracting either an electron or hole theretoward. A “conductive contact layer” or “contact layer” is a layer made of or including at least one material having a resistivity less than that of the “charge layer” of n or p polarity and/or that of an inert layer which does not have either polarity and, therefore, is neutral. Both of the “charge layer” and “contact layer” may be provided by employing, e.g., conventional semiconductor fabrication processes including exemplary steps of, e.g., chemical or physical deposition of substrate layers, doping at least portions of such layers, masking of doped or undoped layers, etching at least portions of such layers, and so on. These layers may be provided by other conventional techniques such as, e.g., direct solution casting, indirect solution casting which requires heat treatment following casting, wafer bonding, and the like. It is appreciated that “charge layers” may be used to collectively refer to any or all “charge layers” of any member and having any polarity such as, e.g., the p polarity, n polarity, and neutral polarity. However, an upper, intermediate, and lower “charge layer” may refer respectively to an uppermost, intermediate, and lowermost “charge layer” of any or all members such as the first member, second member, third member, and so on.

As used herein, the terms “charge layer” and “planar layer” represent any layer which may be made of materials arranged to allow movements of electrons and/or holes thereacross. The “charge layer” is generally a layer made of such materials, while the “planar layer” refers to a layer which may be made of such materials and which are specifically made by conventional semiconductor fabrication processes. Accordingly, the “charge layer” is inclusive of the “planar layer” and to be interpreted as such unless otherwise specified.

The term “connection” is generally synonymous with “electrical connection” and/or “electrical contact.” Therefore, “connection,” “electrical connection,” and/or “electrical contact” generally refer to a macroscopic, planar, and/or microscopic structures which allow passage of electrons and/or holes therethrough, example of which may include, but not be limited to, physical contacts between two or more objects, deposition of a conductive contact layer between, over or below two objects, soldering two or more objects, and the like. Accordingly, when two members are connected, they may contact each other by a series and/or parallel connection. In particular, when such members are connected in series, voltages generated by each member are to be added to each other. When a proposition “to” is used with the terms “connection” and “contact,” it typically refers to a structure in which two or more layers, members, and/or objects are arranged to directly or indirectly touch each other.

To the contrary, the term “contact” generally means a physical contact between two objects. Accordingly, “contacting” layers and/or members refer to those layers and/or members which may be arranged to physically touch each other and to conduct electricity therethrough. Similarly, a “contact layer” represents a layer which provides not only physical contact but also electrical connection of at least two layers, members, and/or objects.

An adjective “adjacent” represents a proximate physical disposition of at least two objects, but does not necessarily imply direct physical contact therebetween. Therefore, “adjacent” members are disposed close to each other but do not necessarily contact each other unless otherwise specified. Similarly, the terms “next to” and “side by side” represent proximate physical dispositions, and do not necessarily imply direct physical contacts therebetween. It is to be understood that, throughout this description, “adjacent members” generally refer to at least two members which are disposed laterally with respect to each other and close to each other, that “adjacent layers” of one member generally represent various charge and/or planar layers which are disposed vertically one over the other, and that “adjacent layers” of “adjacent members” refer to those layers of different members which may be disposed laterally with respect to each other.

As used herein, a proposition “over” may imply vertical physical disposition of one object with respect to a reference object. Similarly, a proposition “below” may imply vertical physical disposition of one object with respect to a reference object. It is to be understood that both of the terms “over” and “below” may or may not represent direct contacts between the object of interest and reference object unless otherwise specified.

Unless otherwise defined in the following specification, all technical and scientific terms used herein have the same meaning as commonly understood by one of ordinary skill in the art to which the present invention belongs. Although the methods or materials equivalent or similar to those described herein can be used in the practice or in the testing of the present invention, the suitable methods and materials are described below. All publications, patent applications, patents, and/or other references mentioned herein are incorporated by reference in their entirety. In case of any conflict, the present specification, including definitions, will control. In addition, the materials, methods, and examples are illustrative only and not intended to be limiting.

Other features and advantages of the present invention will be apparent from the following detailed description, and from the claims.

### BRIEF DESCRIPTION OF THE DRAWING

FIG. 1 is a cross-sectional schematic diagram of a photovoltaic system which includes multiple photovoltaic members each including an intermediate layer according to the present invention;

FIG. 2 is a cross-sectional schematic diagram of a photovoltaic system which includes multiple photovoltaic members without any intermediate layers according to the present invention;

FIG. 3 is a cross-sectional schematic diagram of a photovoltaic system which includes multiple photovoltaic members which are electrically insulated from each other and each of which includes an intermediate layer according to the present invention;

FIG. 4 is a cross-sectional schematic diagram of a photovoltaic system which includes multiple photovoltaic members which are electrically insulated from each other and which does not have any intermediate layers according to the present invention;

FIG. 5 is a cross-sectional schematic diagram of a photovoltaic system which includes multiple photovoltaic members which are connected in series to each other and which form multiple junctions according to the present invention;

FIG. 6 is a cross-sectional schematic diagram of a photovoltaic member which includes a side contact portion according to the present invention;

FIG. 7 is a cross-sectional schematic diagram of another photovoltaic member which includes another side contact portion according to the present invention;

FIG. 8 is a cross-sectional schematic diagram of a photovoltaic member which includes at least one slanted layer according to the present invention;

FIG. 9 is a cross-sectional schematic diagram of a photovoltaic member which includes at least one vertical layer and a side contact portion according to the present invention; and

FIG. 10 is a cross-sectional schematic diagram of another photovoltaic system which includes multiple photovoltaic members which are connected in series through top and bottom contacting layers thereof according to the present invention.

### DETAILED DESCRIPTION OF THE PREFERRED EMBODIMENTS

The present invention generally relates to various photovoltaic systems capable of generating electric energy in response to various electromagnetic waves projected thereupon and, optionally, at least partially transmitting such waves therethrough. More particularly, the present invention relates to planar arrangements and methods of such photovoltaic systems where photovoltaic members are electrically connected in series though top and/or bottom charge and/or planar layers thereof, through substantially horizontal contact layers connecting such top and/or bottom layer, and/or through other equivalent structures without using any conventional vertical interconnects which generally traverse multiple charge and/or planar layers vertically. As will be described herein, such series connections are obtained in such a photovoltaic system by arranging the charge and/or planar layers of adjacent members to have polarities alternating in reverse orders. In other words, the photovoltaic members of such a photovoltaic system are arranged to form at least one p-n junction, at least one p-i-n junction, at least one Schottky junction or other equivalent junctions capable of generating voltages in response to the waves, and the adjacent photovoltaic members are arranged to have such junctions disposed in opposite directions such that the top layers, bottom layers, and/or contact layers which connect such top and/or bottom layers are arranged to connect the adjacent members in series. The present invention also relates to various methods for connecting photovoltaic members in series through their top and/or bottom layers and/or contact layers, and also relates to various process of providing such photovoltaic systems and/or photovoltaic members thereof.

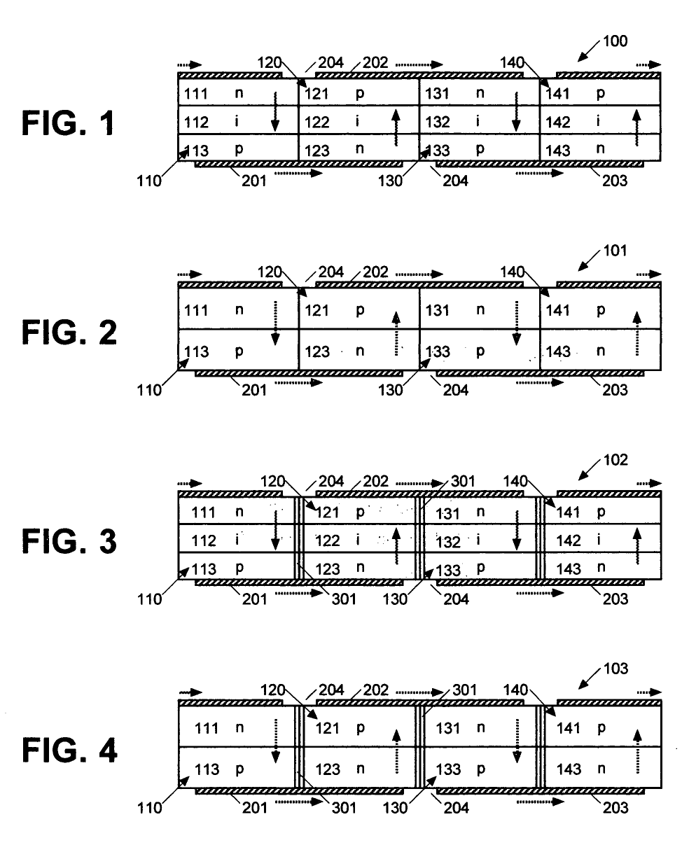

In one aspect of the present invention, a photovoltaic system may include multiple photovoltaic members each of which may be arranged to include multiple charge layers with different polarities, to be disposed laterally side by side, and to be connected to each other through contact layers. FIG. 1 is a cross-sectional schematic diagram of an exemplary photovoltaic system which may include multiple photovoltaic members each including an intermediate layer according to the present invention. Such a PV system 100 generally extends over a length in or along a curvilinear lateral (or horizontal) direction and also extends into a thickness (or depth) along or in a curvilinear vertical direction (or any direction substantially perpendicular to the lateral direction). The exemplary PV system 100 includes multiple PV members 110, 120, 130, 140 which are arranged side by side substantially along the lateral direction. Each of such PV members 110, 120, 130, 140 includes an upper charge layer 111, 121, 131, 141, at least one intermediate layer 112, 122, 132, 142, and a lower charge layer 113, 123, 133, 143, where each of such layers 111-113, 121-123, 131-133, 141-143 is arranged to extend along a layer length in the lateral direction and along a layer thickness in the vertical direction. Such charge layers 111-113, 121-123, 131-133, 141-143 of each PV member 110, 120, 130, 140 are generally arranged to contact each other along the vertical direction, whereas such layers 111-113, 121-123, 131-133, 141-143 are preferably insulated laterally from neighboring layers or to have minimum contact area therebetween. In addition, each charge layer 111-113, 121-123, 131-133, 141-143 is arranged to have one of multiple polarities such as, e.g., a negative or “n” polarity, a positive or “p”, polarity, and an intrinsic, neutral or “i” polarity. For example, the charge layers 111-113, 131-133 of the first and third PV members 110, 130 shown in FIG. 1 are arranged to have, from top to bottom, the n, i, and p polarities, whereas the charge layers 121-123, 141-143 of the second and fourth PV members 120, 140 are arranged to have such polarities arranged in a reverse or opposite order. Accordingly, the PV system 100 of FIG. 1 is arranged to include multiple p-i-n junctions arranged along the lateral direction in an alternating order. It is appreciated that the upper charge layers 111, 121, 131, 141 may be called as top charge layers, while the lower charge layers 113, 123, 133, 143 may be called as bottom charge layers.

The PV system 100 further includes multiple contact layers 201, 202, 203 arranged to connect the PV members 110, 120, 130, 140 in series by connecting adjacent top and/or bottom charge layers. For example, a first contact layer 201 is disposed below or under the first and second lower charge layers 113, 123 to connect such lower charge layers 113, 123 having opposite conductivities, while a second contact layer 202 is placed on, over or above the second and third upper charge layers 121, 131 to connect such upper charge layers 121, 131 having opposite conductivities. In addition, a third contact layer 203 is also disposed below or under the third and fourth lower charge layers 133, 143 to connect such lower charge layers 133, 143 having opposite polarities. Such contact layers 201, 202, 203 are also arranged to extend over a length in the lateral direction and into a thickness in the vertical direction. It is appreciated that the charge layers 111-113, 121-123, 131-133, 141-143 as well as the contact layers 201-203 are preferably arranged to have the lengths greater than their heights and/or thicknesses, although their shapes and/or sizes are not generally critical to the scope of this invention. It is appreciated that the contact layer disposed above the upper or top charge layers 111, 121, 131, 141 may be called as a top contact layer, while the contact layer disposed below the lower or bottom charge layers 113, 123, 133, 143 may be called as a bottom contact layer.

The PV system 100 may be made by providing the first and third contact layers 201, 203 either by depositing such conductive contact layers 201, 203 on a substrate (not shown in the figure) or by depositing a non-conductive layer on the substrate followed by doping corresponding portions thereof into the conductive contact layers 201, 203. In the former embodiment, spaces between the contact layers 201, 203 may be doped to have zero or very little conductivity, if any, or may be filled with non-conductive materials. In this latter embodiment, void space between the contact layers 201, 203 and other void spaces to the left of the first contact layer 201 and to the right of the third contact layer 203 are left with the non-conductive layer which is not doped and, therefore, remains non-conductive. On top thereof, conductive, semiconductive or non-conductive materials are deposited in order to form a lower layer which is selectively doped in order to define the lower charge layers 113, 123, 133, 143 which are arranged to have the n, p, n, and p polarity, respectively. It is appreciated that such lower charge layers 113, 123, 133, 143 are shaped and/or sized such that at least portions of the first and second lower charge layers 113, 123 are disposed over the first contact layer 201, whereas at least portions of the third and fourth lower charge layers 133, 143 are disposed over the third contact layer 203. Semiconductive materials having intrinsic polarity are then deposited thereabove so as to define the intermediate layers 112, 122, 132, 142 over the first, second, third, and fourth lower charge layers 111, 121, 131, 141, respectively. Conductive, semiconductive or non-conductive materials are then deposited thereover in order to form an upper layer which is further doped to define the upper charge layers 111, 121, 131, 141 each of which is arranged to have the p, n, p, and n polarity, respectively, and which are disposed above the corresponding intermediate layer 112, 122, 132, 142, respectively. The second contact layer 202 is then deposited using the procedures similar to those for the first and third contact layers 201, 203 as described above. More particularly, the second contact layer 202 is deposited to contact at least portions of the second and third upper charge layers 111, 121, 131, 141. As a result, the PV members 110, 120, 130, 140 have alternating polarities or junctions such that the first and third members 110, 130 define the n-i-p junctions, whereas the second and fourth members 120, 140 define the p-i-n junctions. In addition, the contact layers 201-203 are arranged to contact the adjacent charge layers, 113 and 123, 121 and 131, 133 and 143, which have opposite polarities.

More particularly, the PV system 100 may be fabricated employing many different conventional semiconductor fabrication processes. First, a mask is patterned and then disposed on a support and planar lower contact layers 201, 203 are deposited on the support along the lateral direction. In order to prevent short circuit between the contact layers 201, 203, gaps 204 are provided therebetween or may be filled with dielectric material in a subsequent masking and/or depositing step. Another mask is applied on top of the contact layers 201, 203 and planar lower charge layers 113, 133 having the first polarity such as the p polarity are deposited thereon in the lateral direction. A new mask is disposed or the existing mask is moved by a stepper, and the planar lower charge layers 123, 143 having the second polarity such as the n polarity are then deposited along the lateral direction, e.g., by filling gaps formed between the adjacent lower charge layers having the p polarity therewith. The lower charge layers 113, 123, 133, 143 may alternatively be formed by depositing a layer of intrinsic materials over the contact layers 201-203 and selectively doping its different regions to provide alternating polarities. The intermediate layers 112, 122, 132, 142 are deposited over the lower charge layers 113, 123, 133, 143 as a single layer along the lateral direction. Alternatively, such intermediate layers 112, 122, 132, 142 may first be deposited on the lower charge layers of one polarity, and subsequently on those of the opposite polarity along the lateral direction. Using the same mask or by applying a new mask in the similar position, the planar upper charge layers 111, 131 having the first polarity such as the p polarity are deposited in the lateral direction substantially on, above, and/or over the lower charge layers 113, 133 of the second polarity such as the n polarity along the vertical direction. Thereafter, a new mask may be disposed or the existing mask is moved by a stepper motor so as to deposit the planar upper charge layers 121, 141 having the second polarity along the lateral direction, e.g., by filling the gaps formed between adjacent upper charge layers 111, 131 having the first polarity. In the alternative, the upper charge layers 111, 121, 131, 141 may be formed by depositing a layer of intrinsic materials over the intermediate layers 112, 122, 132, 142 and selectively doping its different regions so as to provide alternating polarities. Another mask is then disposed on the upper charge layers 111, 121, 131, 141 and the planar upper contact layer 202 is deposited thereon in the lateral direction to connect multiple PV members in series.

As briefly discussed hereinabove, the upper, intermediate, and/or lower charge layers may be fabricated by depositing a single planar layer along the lateral direction and doping different regions of such a layer with appropriate dopants. For example, the lower charge layers may be provided, e.g., by depositing a layer of undoped amorphous Si in the lateral direction over the bottom contact layers 201, 203. A first doping mask is placed and a p polarity dopant is introduced through openings of the mask to form the lower charge layers 113, 133 having the p polarity. The first mask is then moved by a given distance or a second doping mask is placed, and an n polarity dopant is introduced through the openings to form the lower charge layers 123, 143 having the n polarity. Thereafter, the mask is removed and the layers are heated for drive-in diffusion so as to allow the dopants to diffuse into the lower charge layers 113, 123, 133, 143 along the vertical direction. After providing the lower charge layers 113, 123, 133, 143, a layer of undoped or intrinsic amorphous Si is deposited thereover in order to form the intermediate layers 112, 122, 132, 143. Another layer of undoped amorphous Si may then be deposited, the third doping mask is positioned thereover, and a p polarity dopant is applied in order to form the upper charge layers 121, 141 having the p polarity. After moving the mask or disposing a fourth mask, an n polarity dopant is introduced through openings thereof to provide the upper charge layers 111, 131 having the n polarity. The mask is removed and the doped upper charge layers 111, 121, 131, 141 are heated for drive-in diffusion to allow the dopants to diffuse thereinto. Another mask is disposed on the upper charge layers 111, 121, 131, 141, and the planar upper contact layer 202 is deposited thereon in the lateral direction to connect multiple PV members 110, 120, 130, 140 in series. The doping and/or drive-in-diffusion described hereinabove may produce demarcation zones between the layers of opposite polarities, which is less controllable than the layer-by-layer deposition methods described in the preceding paragraph. However, the former process generally provides a simpler and cost-effective technique when the finer demarcation between the layers may not be strictly required. In all of such processes, each layer of the PV system 100 may be deposited by various conventional fabrication processes such as, e.g., chemical or physical deposition, direct or indirect solution casting of precursors followed by heat treatment, wafer bonding, and the like.

In the alternative, such a PV system 100 may be provided through non-planar methods as well. In one exemplary method, each photovoltaic member 110, 120, 130, 140 is provided by stacking thin layers having different polarities arranged as shown in the figure and then placed adjacent to each other. The first contact layer 201 is then disposed under at least portions of the lower charge layers 113, 123 of the first and second members 110, 120 in order to connect the first and second members 110, 120 in series therethrough. The second contact layer 202 is also disposed over at least portions of the upper charge layers 121, 131 of the second and third members 120, 130 in order to connect the second and third members 120, 130 in series therethrough, and the third contact layer 203 is disposed under at least portions of the lower charge layers 133, 143 of the third and fourth members 130, 140 so as to connect such members 130, 140 in series therethrough. In another exemplary method, a thin first layer is provided, where portions thereof are selectively doped to have alternating polarities such as, e.g., p, n, p, and n. A thin second layer is also provided to have inert polarity. A thin third layer is also provided, where portions thereof are selectively doped to have alternating but reverse polarities such as, e.g., n, p, n, p. The first, second, and third layers are then sequentially stacked one over the other while aligning the portions of different polarities of the first layer with the corresponding portions of the third layer, thereby forming multiple members 110, 120, 130, 140. The contact layers 201-203 are then disposed over or below the first or third thin layers in order to connect multiple members 110, 120, 130, 140 in series sequentially.

In operation, the PV system 100 is illuminated by a light source emitting electromagnetic waves which have a preset range of wavelengths. The intrinsic or intermediate layers 112, 122, 132, 142 of the PV members 110, 120, 130, 140 absorb photons of such electromagnetic waves 100 and convert them into electron-hole pairs. The electrons and holes are then separated by an electric field exerted between the charge layers 111, 113, 121, 123, 131, 133, 141, 143 of the PV members 110, 120, 130, 140, which results in generation of electric voltage. Therefore, the electrons flow toward the charge layers which have the p conductivity and, therefore, serve as electron collector layers, whereas the holes flow toward the charge layers which have the n conductivity and, thus, serve as hole collector layers. The electrons which are collected by the electron collector layer 113 of the first PV member 110 then flow through the first contact layer 201 and enter the hole collector layer 123 of the second PV member 120 disposed adjacent to the first PV member 100, as indicated by the arrows shown in the figure, thereby forming a series connection between the first and second PV members 110, 120. Similarly, the second PV member 120 is connected in series to the third PV member 130 by the second contact layer 202, while the third PV member 130 is connected in series to the fourth PV member 140 by the third contact layer 203. As a result, all four PV members 110, 120, 130, 140 are connected to each other in series and generate driving voltage which is greater than voltage generated by each of such PV members 110, 120, 130, 140. Further electric connections are provided to the n polarity layer 111 of the first PV member 110 and the p polarity layer 141 of the last PV member 140 and an external load is disposed between the electric connections. Accordingly, the external load and PV system 100 form a closed circuit, and the electric current flows through the closed circuit and the external load is supplied with requisite electricity as long as the photons continue to generate the electron-hole pairs in the intermediate layers 112, 122, 132, 142 of the PV system 100.

The above charge layers 111-113, 121-123, 131-133, 141-143 of the PV system 100 may be made of and/or include any conventional materials commonly used for photovoltaic devices such as, e.g., solar cells, semiconductor devices, and the like. Examples of such materials may include, but not be limited to, silicone (Si) containing materials such as, e.g., amorphous Si, hydrogenated amorphous Si, hydrogenated amorphous Si carbon, polycrystalline Si, microcrystalline Si, and the like. These Si-containing materials may be doped with conventional n polarity dopants such as, e.g., phosphine (PH₃) and/or p polarity dopants such as, e.g., BF₃, diborane (B₂H₆), and the like, to provide proper electric conductivity and/or polarity. The feedstock for the Si-containing materials may be any of silane (SiH₄), disilane (Si₂He), tetramethyl silane (Si(CH₃)₄), SiF₄, SiHF₃, SiH₂Cl₄, CHN(SiH₃)_{4-N} where N is an integer between 0 and 3, carbon-based feedstock or germanium based feedstock. The feedstock may also include materials having a general formula SiNH_{2N+2-M}Y_{M} where N and M are positive integers, (2N+2−M) must be non-negative, and Y is a halogen such as fluorine (F), chlorine (Cl), bromine (Br), iodine (I), and the like. Other materials may also be used to make at least one layer of the PV members, where examples of such materials may include, but not be limited to, selenide compounds such as, e.g., Cu In diselenide, gallium selenide compounds such as, e.g., Cu in gallium selenide, hydrogenated amorphous germanium, and the like. Details of fabrication of various charge layers 111-113, 121-123, 131-133, 141-143 of the PV system 100 are well disclosed in prior art, e.g., U.S. Pat. No. 6,077,722 to Jansen et al. which is herein incorporated by reference in its entirety. It is to be understood, however, that such charge layers 111-113, 121-123, 131-133, 141-143 may be made of and/or include other materials as long as they may generate proper electric voltage when projected by the electromagnetic waves.

The conductive contact layers 201-203 may be made of and/or include any material capable of conducting the electrons and/or holes therethrough, e.g., having electric conductivity of conductors or semiconductors, i.e., substances or mixtures with electric resistivity ranging up to about 106 ohm-cm. Thin films of metals, inorganic materials, conductive polymers or mixture thereof may be used to form the above contact layers 201-203 which may optionally be transparent, opaque, and/or translucent as well. However, such contact layers 201-203 may preferably be made of transparent materials when they are to be disposed on surfaces of the PV members 110, 120, 130, 140 and to transmit the waves to the layers generating the electron-hole pairs. Examples of such film-forming conductive materials may include, but not be limited to, aluminum, molybdenum, platinum, niobium, titanium, chromium, silver, bismuth, antimony, steel, iron, alloys or oxides, homogeneous-, blend- and/or copolymers of double-bonded, triple-bonded, aromatic ring-containing polymers, conjugated polymers, and so on. In addition, the contact layers 201-203 may also be provided with conventional polymers which are mixed with or including conductive materials therein, e.g., metal particles or powder, activated charcoal, and the like. Examples of such polymers may include, but not be limited to, homogeneous-, blend- or copolymers of styrene, ethylene, propylene, butadiene, isoprene, acrylate, carbonate, acetate, ester, cellulose, vinyl chloride, urethane, terephthalate, methyl-methacrylate, amide, glycol, arylene, ethers acrylic, sulfones, epoxy, dienes, phenylene oxide, cyclopentadiene, cyanoprene, vinyl-toluene, olefins, alpha-olefins, polyolefins, and the like. In addition, rubbers, resins or other elastomers such as natural rubber, butyl rubber, chlorinated butyl rubber, polybutadiene rubber, acrylonitrile-butadiene rubber, ABS, styrene rubber, and polychloroprene may be used. Furthermore, substituted forms of the above-described polymers may also be used where one or more atoms are replaced by one or more molecules such as chlorine, and oxygen, and/or by one or more groups such as methyl-, ethyl-, propyl-, isopropyl-, vinyl-, acrylic, and phenyl. Any mixture of the above-mentioned material as well as any other heat-sealable materials may also be employed. In the alternative, the contact layers 201-203 may further be made of conventional polymers not mixed with conductive materials which includes various side groups which enhance electron- and/or hole-transporting properties thereof. Examples of metallic and/or nonmetallic conductive materials may include, but not be limited to, aluminum, magnesium, germanium, silicon, zinc, quartz, calcium, silica, copper, nickel, tungsten, lead, silver, gold, iron, stainless steel, their mixtures, oxides thereof, conductive compounds thereof, and the like. Other materials may also be used for the contact layers 201-203 as long as they allow proper conductivity to the electrons and/or holes.

In another exemplary embodiment of the same aspect of the present invention, the photovoltaic system may include multiple photovoltaic members each of which includes the p-polarity and n-polarity charge layers directly contacting each other. For example, FIG. 2 shows a cross-sectional schematic diagram of another photovoltaic system which includes multiple photovoltaic members each having p and n-polarity layers without any intermediate layers disposed therebetween according to the present invention. As shown in the figure, a PV system 101 of FIG. 2 is substantially identical to that of FIG. 1, e.g., the system 101 includes four photovoltaic members 110, 120, 130, 140 disposed laterally side by side and connected to each other in series. However, each of such PV members 110, 120, 130, 140 do not include any intermediate or intrinsic layers between its upper charge layers 111, 121, 131, 141 and lower charge layers 113, 123, 133, 143. Such a PV system 101 may be readily fabricated by the similar processes described in conjunction with FIG. 1.

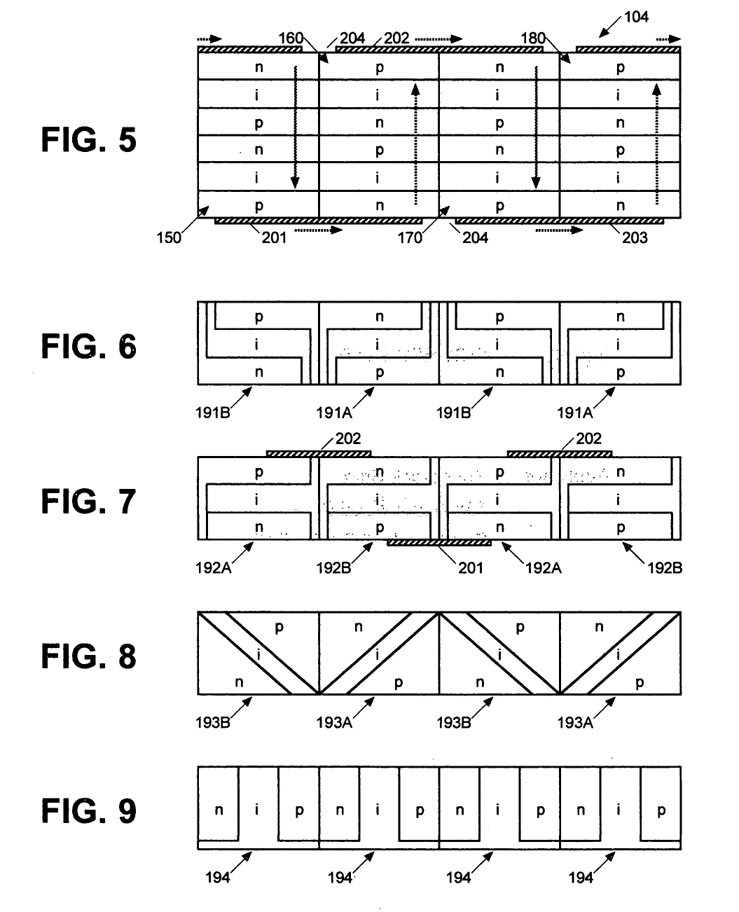

The foregoing PV systems 100, 101 are arranged so that the charge layers 111-113, 121-123, 131-133, 141-143 of each PV member 110-140 may be disposed substantially adjacent to each other along the vertical direction and provide the p-i-n and/or p-n junctions formed therealong. Each pair of the adjacent PV members 110-140, however, may also form at least one p-n or n-p junction along the lateral direction between the neighboring charge layers. When these adjacent charge layers contact each other as shown in FIGs. 1 and 2, (and FIG. 5 infra), a short circuit may be formed and allow the electrons and holes to recombine at the p-n and/or n-p junction. The electron-hole recombination leaks the electric current and may be a reason for lower voltage ratings of the PV systems 100, 101. Thus, in another aspect of the present invention, a photovoltaic system may include at least one insulation layer capable of preventing or minimizing energy losses caused by formation of undesirable contacts between various charge or planar layers thereof. FIG. 3 is a cross-sectional schematic diagram of a photovoltaic system including multiple photovoltaic members which are electrically insulated from each other and each of which includes an intermediate layer according to the present invention. Such a PV system 102 is substantially identical to that of FIG. 1, e.g., having four PV members 110, 120, 130, 140 disposed laterally and side by side and connected to each other in series. However, the PV system 102 includes insulation layers 301 arranged to extend substantially along the vertical direction and to be disposed between the PV members 110, 120, 130, 140 to prevent or minimize contact between the neighboring charge layers of different PV members 110, 120, 130, 140. The insulation layers 301 may be made of or include any dielectric materials such as Si oxide and may have thicknesses which are thick enough to prevent or minimize formation of short circuits between the neighboring charge layers of the adjacent PV members and thin enough to maximize the usable area of the PV system 102. The insulation layers 301 may not necessarily be provided between adjacent intermediate layers 112, 122, 132, 142 which do not necessarily form short circuits. Accordingly, the intermediate layers 112, 122, 132, 142 may be deposited as a single layer of intrinsic or neutral material.

The above insulation layers 301 may be provided using various processes. In one exemplary method, the insulation layers 301 are to be formed after providing multiple charge layers 111-113, 121-123, 131-133, 141-143. For example, the insulation layers 301 are provided by etching out contacting regions between the adjacent members 110, 120, 130, 140 to form trenches having preset widths and depths and by filling the trenches with dielectric or other insulating materials. Alternatively, a portion of the trench is formed while providing each charge layer of the PV members 110, 120, 130, 140 so that the insulation layer 301 is completed when all of or at least a substantial portion of the charge layers 111-113, 121-123, 133-133, 141-143 may be completed. It is to be understood that the insulation layer 301 may be formed by any appropriate conventional methods as long as such an insulation layer may be able to prevent or at least minimize the formation of short circuits between the charge layers of the adjacent PV members 110, 120, 130, 140. It is also to be understood that shapes and/or sizes of the insulation layers 301 are not material to the scope of this invention as long as the insulation layers may accomplish the foregoing objectives. Other than such insulation layers 301, the PV system of FIG. 3 may be provided by the similar processes described in conjunction with FIG. 1.

In another exemplary embodiment of the same aspect of the present invention, the photovoltaic system may include multiple PV members each of which includes the p-polarity and n-polarity charge layers directly contacting each other and each of which is isolated by at least one insulation layers disposed between the adjacent members. For example, FIG. 4 is a cross-sectional schematic diagram of a photovoltaic system which includes multiple photovoltaic members which are electrically insulated from each other and which does not have any intermediate layers according to the present invention. As shown in the figure, a PV system 103 of FIG. 4 is substantially identical to that of FIG. 3, e.g., the system 103 includes four PV members 110, 120, 130, 140 which are disposed laterally side by side, insulated from each other by the insulation layers 301, and connected to each other in series through the contact layers 201-203. However, such a PV member 110, 120, 130, 140 does not include any intermediate or intrinsic layers between its upper charge layers 111, 121, 131, 141 and lower charge layers 113, 123, 133, 143. Such a PV system 101 may be readily fabricated by the similar processes described in conjunction with FIGS. 2 and/or 3.

In another aspect of the present invention, a photovoltaic system includes multiple photovoltaic members each of which may include multiple series-connected p-n junctions, p-i-n junctions, Schottky junctions, and/or other junctions for generating voltage in response to the waves projected thereupon. For example, FIG. 5 is a cross-sectional schematic diagram of a photovoltaic system including multiple photovoltaic members each of which includes multiple junctions and which are connected in series to each other according to the present invention. A PV system 104 of FIG. 5 includes four PV members 150, 160, 170, 180 arranged laterally and side by side. Each PV member 150, 160, 170, 180 includes two p-i-n junctions disposed one over the other along the vertical direction and connected in series to each other. A first contact layer 201 is arranged to extend in the lateral direction and disposed below the first and second PV members 150, 160 so as to connect their lower charge layers with opposite polarities. A second contact layer 202 is arranged to extend in the lateral direction and disposed over the second and third PV members 160, 170 so as to connect their upper charge layers with opposite polarities. A third contact layer 203 is also arranged to extend along the lateral direction and disposed below the third and fourth PV members 170, 180 so as to connect the lower charge layers of the third and fourth PV members 170, 180 connect their lower charge layers having opposite polarities. Thus, all eight p-i-n junctions formed in four PV members 150, 160, 170, 180 may be connected in series. It is understood that the PV system 104 may further include multiple insulation layers disposed between the laterally adjacent charge layers and arranged to prevent or at least minimize the formation of short circuits therebetween. It is also understood that the PV members 150, 160, 170, 180 may not include any intermediate layers so that the contacting charge layers with alternating polarities define multiple p-n junctions. The PV system 104 may also be provided by the processes similar to those described in conjunction with FIG. 1, except that multiple p-i-n junctions thereof may be provided by repeating the steps of providing the charge layers having different polarities. When the PV system 104 is arranged to include the insulation layers and/or to be comprised of the charge layers with the p- and n-polarities only, it may also be provided by the processes similar to those described in conjunction with FIGS. 3 and 4.

In operation, the PV system 104 is illuminated by a light source emitting electromagnetic waves having a preset range of wavelengths. Various charge layers of the PV members 150, 160, 170, 180 which are arranged to be at least partially transparent or translucent then transmit such waves to the intrinsic or intermediate layers which may absorb photons of the waves and convert at least a portion thereof into the electron-hole pairs which are then separated into electrons and holes by an electric field exerted between the charge layers to generate electric voltage. Accordingly, the electrons flow toward the charge layers which have the p conductivity and serve as electron collector layers, while the holes flow toward the charge layers which have the n conductivity and, therefore, serve as hole collector layers. The electrons which flow through two p-i-n junctions of such a first member 150 are collected by the lower charge layer (i.e., electron collector layer) of the first PV member 150 and flow through the first contact layer 201 and then enter the lower charge layer (i.e., hole collector layer) of the second PV member 160 disposed adjacent to the first PV member 150, as indicated by the arrows shown in the figure, thereby forming a series connection between the first and second PV members 150, 160. Similarly, the second PV member 160 is connected in series to the third PV member 170 by the second contact layer 202, whereas the third PV member 170 is connected in series to the fourth PV member 180 by the third contact layer 203. As a result, all eight p-i-n junctions of the PV members 150, 160, 170, 180 may be connected to each other in series and generate driving voltage which may be greater than voltage generated by each of such PV members 150, 160, 170, 180. Further electric connections are provided to the n polarity layer of the first PV member 150 and the p polarity layer of the last PV member 180 and an external load is disposed between the electric connections. Thus, the external load and the PV system 104 form a closed circuit, and the current flows through the closed circuit and the external load is supplied with requisite electricity as long as the photons continue to generate the electron-hole pairs in the intermediate layers of the PV system 104. It is understood that, similar to that of FIGS. 1 to 4, the PV members 150, 160, 170, 180 of the PV system 104 of FIG. 5 may be connected in series by the relatively horizontal contact layers 201-203, without using any vertical interconnect or contact layers.

In another aspect of the present invention, adjacent PV members may further be connected to each other through their top and/or bottom charge and/or planar layers which are arranged to contact each other, but not through the contact layers described hereinabove. Thus, the first and second PV members may be connected to each other through their top (or bottom) charge and/or planar layers, while the second and third PV members may be connected to each other through their bottom (or top) charge and/or planar layers, and the like. Accordingly, the PV members are connected to each other in an alternating fashion like the contact layers as exemplified in the foregoing figures. Because such adjacent charge and/or planar layers of adjacent PV members are also arranged to have different or opposite polarities, the PV members may be connected to each other in series and, therefore, the PV system may generate the driving voltage which is greater than the voltage generated by each of the PV members. In such an embodiment, the insulation layers are not preferably provided between such top and/or bottom charge and/or planar layers connected to each other, while other adjacent charge and/or planar layers may be insulated from each other by the insulation layers described hereinabove.

To increase area of contacts therebetween and to decrease the resistance therethrough, the top and/or bottom charge and/or planar layers of such an embodiment may also have shapes, sizes, and/or arrangements which are different from those described in FIGS. 1 to 5. For example, flowing FIGS. 6 to 10 exemplify several different embodiments in which the contacting top (or bottom) charge and/or planar layers are modified for such purposes.

In one exemplary embodiment, one or more charge and/or planar layers of the PV member may have side contact portions extending vertically beyond their thickness to increase contact areas with adjacent charge and/or planar layers of the adjacent PV member having opposite polarities. FIG. 6 is a cross-sectional schematic diagram of a photovoltaic member having vertically extending side contact portions according to the present invention. An exemplary PV system may include two types of PV member 191A, 191B each including three charge layers extending horizontally or laterally and forming a single p-i-n junction. In the first type of such PV members 191A, one side of the upper charge layer of the n conductivity is arranged to protrude beyond the intermediate layer and to extend downwardly along the vertical direction in order to form a side contact portion and to encompass the same sides of the intermediate and lower charge layers. An opposing side of the lower charge layer having the p conductivity is also arranged to protrude beyond the intermediate layer and to extend upwardly along the vertical direction in order to form another side contact portion and to encompass the same sides of the intermediate and upper charge layers. One side of the intermediate layer extends upwardly, while its other side extends downwardly so as to avoid direct contact between the upper and lower charge layers. The PV members 191B of the second type is generally arranged to have a mirror image of the PV members 191A of the first type, except that such PV members of different types are arranged to have the polarities arranged in an opposite order. Therefore, in the second type of such PV members 191B, one side of the upper charge layer with the p conductivity is arranged to protrude beyond the intermediate layer and to extend downwardly along the vertical direction so as to form a side contact portion and to encompass the same sides of the intermediate and lower charge layers. An opposing side of the lower charge layer of the n conductivity is arranged to protrude beyond the intermediate layer and to extend upwardly along the vertical direction in order to form another side contact portion and to encompass the same sides of the intermediate and upper charge layers. In addition, one side of the intermediate layer extends upwardly, while its other side extends downwardly so as to avoid direct contact between the upper and lower charge layers. Further characteristics of various charge layers of the PV members 191A, 191B may also be similar or identical to those of FIGS. 1 to 5.

In operation, multiple PV members 191A, 191B are provided by arranging polarities of some of the PV members 191A to form n-i-p junctions from top to bottom, while those of other members 191B to form p-i-n junctions from top to bottom. The PV members 191A, 191B are disposed laterally side by side and arranged to contact each other through their side contact portions, while arranging such PV members 191A, 191B in an alternating fashion. In addition, the adjacent PV members may be oriented such that adjacent side contact portions have different polarities. Thus, the PV members 191A, 191B contact each other in series and the PV system can generate the driving voltage which is greater than the voltage generated by each of the PV members 191A, 191B, without employing the lateral contact layers of the present invention and/or conventional vertical interconnects as commonly used in planar semiconductors.

The intermediate layers of the PV members may be arranged to have other configurations. For example, FIG. 7 shows a cross-sectional schematic diagram of another photovoltaic member including another side contact portion according to the present invention. An exemplary PV system may include two types of PV member 192A, 192B each of which has three charge layers extending horizontally or laterally and forming a single p-i-n or n-i-p junction. In the first type of the PV members 192A, one side of the upper charge layer of the p conductivity protrudes beyond the intermediate layer and to extend downwardly along the vertical direction in order to form a side contact portion and to encompass the same sides of the intermediate and lower charge layers. An opposing side of the intermediate layer is arranged to protrude vertically upward and downward beyond the upper and lower charge layers so as to electrically insulate the upper and lower charge layers from the charge layers of an adjacent PV member 192B. The lower charge layer of the n conductivity is disposed between the protruded sides of the upper charge layer and intermediate layer. Accordingly, such a lower charge layer may not be in direct contact with the charge layers of the adjacent PV member 192B. Th PV members 192B of the second type may be typically similar to those 192A of the first type, except that such PV members 192B of the second type form the p-i-n junctions oriented in an opposite direction to the p-i-n junctions of the PV members 192A of the first type. It is appreciated that the adjacent PV members 192A, 192B of different types are disposed laterally and side by side and, therefore, that the charge layers of the opposite (i.e., p and n) polarities of different PV members 192A, 192B are juxtaposed with respect to each other. It is also appreciated that, in contrary to the symmetric arrangements of the PV members 191A, 191B of FIG. 6, the PV members 192A, 192B of FIG. 7 are disposed while maintaining the same orientation. Because the intermediate layers effectively insulate the charge layers of one PV member from those layers of the adjacent PV members, such an embodiment does not form any direct contact between the charge layers of the neighboring PV members. Accordingly, the top and bottom contact layers described hereinabove are employed to connect adjacent PV members in series through their uppermost and/or lowermost charge layers. By varying shapes of one or more of the charge layers, the uppermost charge layers of the adjacent PV members may be connected in series through the top contact layers, while the lowermost charge layers of the PV members may be directly connected to each other. In the alternative, the uppermost charge layers may be directly connected to each other, whereas the lowermost charge layers may be connected in series through the bottom contact layers. Further characteristics of various charge and/or planar layers of the PV members 192A, 192B may be similar or identical to those of FIGS. 1 to 6.

In operation, multiple PV members 192A, 192B are provided by arranging polarities of some of the PV members 192A to form p-i-n junctions from top to bottom, while those of other members 192B to form n-i-p junctions from top to bottom. The PV members 192A, 192B are disposed laterally side by side and arranged to maintain the same orientation such that neighboring PV members 192A, 191B are insulated from each other by the intervening protruded portions of the intermediate layers. Thereafter, the top and bottom contact layers are provided respectively over the upper charge layers and below the lower charge layers of the PV members in an alternating mode. Therefore, the PV members 192A, 192B are connected to each other in series in order to enable the PV system to generate the driving voltage which is greater than the voltage generated by each of the PV members 192A, 192B, without employing the directly contacting charge layers of the present invention and/or conventional vertical interconnects as commonly used in planar semiconductors.

Various charge layers of the PV members may be provided at angles. For example, FIG. 8 is a cross-sectional schematic diagram of an exemplary photovoltaic member including at least one slanted layer according to the present invention. An exemplary PV system may include multiple PV members each of which may include three charge layers disposed at angles and forming a single p-i-n or n-i-p junction. As illustrated hereinabove, such an arrangement may be provided by depositing the charge and intermediate layers slightly angled along the lateral direction by, e.g., uneven deposition or etching of such layers. These angled arrangements may also be provided by depositing one or more lateral layer, disposing the layers at an angle in the lateral direction, and etching or chipping the layers in the lateral direction. Similar to the exemplary embodiments shown in FIGS. 6 and 7, the PV system of FIG. 8 also includes two types of PV members 193A, 193B. In the first type of the PV members 193A, the charge layers including the intermediate layer are angled downward from left to right and form p-i-n junctions. It is appreciated that at least a portion of the intermediate layer may be shaped and sized to be exposed through a top surface of the PV member 193A, implying that an entire portion of the lower charge layer is not exposed therethrough. The PV members 193B of the second type may be typically similar to those 193A of the first type, except that such PV members 193B of the second type may be angled from right to left and form mirror images of those members 193A of the first type. In addition, the PV members 193B of the second type form n-i-p junctions from top to bottom, thereby ordering the polarities of the layers in an opposite direction to those of the p-i-n junctions of the PV members 193A of the first type. Because the adjacent PV members 193A, 193B of different types may be disposed laterally side by side, the charge layers of opposite (i.e., p and n) polarities of different PV members 193A, 193B may be connected to each other in series without employing any contact layers. Further characteristics of various charge and/or planar layers of the PV members 193A, 193B may be similar or identical to those of FIGS. 1 to 7. In addition, operational characteristics of the PV system of FIG. 8 is similar to those of the PV system exemplified in FIG. 6.

The PV members may be connected in series without using conventional vertical interconnects through vertically extending charge layers. For example, FIG. 9 depicts a cross-sectional schematic diagram of a photovoltaic member which includes at least one vertical layer and a side contact portion according to the present invention. An exemplary PV system includes multiple identical PV members 194 each of which may include a single p-i-n junction or a p-n junction arranged at a substantially right angle with respect to the lateral direction. That is, charge layers having p and n polarities are typically arranged to predominantly extend vertically so that their heights are greater than their lengths and/or widths. An intermediate layer is arranged to protrude beyond the lengths of the charge layers having the p and n polarities along the lateral direction and under (or over) the charge layers. In case the PV members 194 should form a tandem PV system where another PV member is disposed thereunder, a lower portion of one charge layer may also be extended along the lateral direction in order to increase contact areas between the charge layers having different polarities. Other characteristics of various charge and/or planar layers of the PV members 194 may be similar or identical to those of FIGS. 1 to 8. In addition, operational characteristics of the PV system of FIG. 9 is generally similar to those of the PV systems exemplified hereinabove.

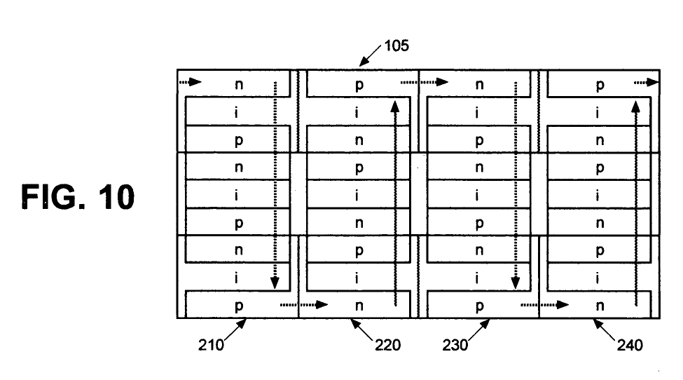

As briefly described hereinabove and in another aspect of the present invention, a PV system may also include multiple PV members at least one of which may be arranged to form multiple identical or different junctions therein. Foe example, FIG. 10 is a cross-sectional schematic diagram of another photovoltaic system having multiple photovoltaic members which are connected in series through top and bottom contact layers thereof according to the present invention. An exemplary PV system 105 includes four PV members 210, 220, 230, 240 each of which includes three n-i-p junctions vertically stacked one over the other and which are disposed laterally side by side. Uppermost n-i-p junctions of the PV members 210, 230 are disposed adjacent to uppermost p-i-n junctions of the PV members 220, 240, while intermediate layers of these PV members 210, 220, 230, 240 are arranged to extend upwardly and downwardly to prevent leakage current between adjacent PV members. A lowermost n-i-p junction of the PV member 210 may be disposed adjacent to a lowermost p-i-n junction of the PV member 220. The lowermost charge layer of the PV member 210 having the p polarity is connected to a lowermost charge layer of the adjacent PV member 220 of the n polarity in series through protruded side portions of such lowermost charge layers. The charge layers of a middle n-i-p junction of the PV member 210 and those of a middle p-i-n junction of PV member 220 may be insulated from each other by a dielectric insulation layer as shown in FIG. 10 or, in the alternative, their intermediate layers may be extended vertically for such an insulation. Other PV members 230, 240 may further be arranged to have similar layer structure and electrical connections. Therefore, electrons may flow through the PV system 105 along a path starting from the uppermost n polarity charge layer of the PV member 210, through the PV member 210 vertically and downwardly, to the lower-most charge layer having the p polarity of the PV member 210, to the lowermost charge layer of the n polarity of the PV member 220 in the lateral direction, through the PV member 220 vertically and upwardly, to the uppermost charge layer of the p polarity of the PV member 220, to the uppermost charge layer of the n polarity of the PV member 230 along the lateral direction, through the PV member 230 vertically and downwardly, to the lowermost charge layer of the p polarity of the PV member 230, to the lowermost charge layer of the n polarity of the PV member 240 along the lateral direction, through the PV member 220 vertically and upwardly, and to the uppermost charge layer of the p polarity of the PV member 240. Therefore, the PV system 105 connects four PV members 210, 220, 230, 240 in series, each including three n-i-p or p-i-n junctions, and generates the driving voltage which may be about twelve times greater than that generated by a single PV member. It is appreciated that the same embodiment shown in FIG. 10 may be interpreted as a PV system comprising four columns of PV members, where each column includes three PV members each forming a p-i-n or n-i-p junction and stacked vertically one over the other. It is further appreciated that the shapes, sizes, and/or arrangements of the charge layers may be modified as long as the PV members are connected in series laterally through the uppermost and/or lowermost charge layers or through the horizontal contact layers and as far as such a PV system may generate the driving voltage as described above.

Configurational and/or operational variations and/or modifications of the above embodiments of the foregoing exemplary photovoltaic systems and their various members also fall within the scope of the present invention.

It is appreciated that the foregoing exemplary embodiments of various PV systems may also be generalized to other embodiments where PV systems include two, three or more PV members which are disposed laterally side by side and connected in series. For example, a PV system may include M PV members where N of such M PV members are disposed adjacent to each other substantially along the lateral direction and where M and N are both integers and M>N>1. A j-th PV member of such N PV members may include a j-th upper charge layer and a j-th lower charge layer, where j is an integer and N>j>1. At least a portion of the j-th upper charge layer may be disposed over at least a portion of the j-th lower charge layer substantially along the vertical direction. When k is an odd integer and (N−1)>k>1, an upper charge layer of the k-th PV member may also be disposed adjacent to an upper charge layer of a (k+1)th PV member of the opposite polarity in order to connect the k-th PV member in series with the (k+1)th PV member. In contrary, when k is an even integer and (N−1)>k>1, a lower charge layer of a k-th PV member may be disposed adjacent to a lower charge layer of a (k+1)th PV member of the opposite polarity and form a series connection therewith. By repeating the foregoing structures, such N PV members may be connected in series. The upper or lower charge layers of the PV members disposed at the opposing ends of the PV system may be fabricated to provide an electric contact with an external circuit or to form lead-out electrodes and/or lead-out layers. When desirable, other layers may be disposed over or below the conductive layers such that the contact layers may be sandwiched or buried between the upper and lower charge layers of the PV members.

Alternatively, such a PV system may include at least N-1 conductive contact layers which are arranged to extend substantially along the lateral direction. When k is an odd integer and (N−1)>k>1, a k-th conductive contact layer may be disposed over at least a portion of a k-th upper charge layer of a first conductivity and over at least a portion of a (k+1)th upper charge layer of a second polarity so as to connect the k-th upper charge layer with the (k+1)th upper charge layer. To the contrary, when k is an even integer and (N−1)>k>1, a k-th contact layer may be disposed below at least portions of a k-th lower charge layer of the second conductivity and a (k+1)th lower charge collector layer of the first conductivity in order to connect the k-th lower charge layer with the (k+1)th lower charge layer if k is an even integer. The upper and/or lower charge layers of the PV members disposed at opposing ends of the PV system may further be fabricated to provide an electric contact with an external circuit or to form lead-out electrodes or lead-out layers. When desirable, the contacting portions such as the side contact portions may be provided to a layer sandwiched or buried between the upper and lower layers of the PV member.

It is understood that, in order to connect (2N+1) PV members in series which may be arranged to be disposed laterally side by side along the lateral direction and to have alternating conductivities, N electric contacts may have to be provided to alternating pairs of upper charge layers, while another N electric contacts may have to be provided to alternating pairs of lower charge layers, with two lead-out contacts to the PV members disposed at opposing ends of the PV system. Therefore, when each PV member includes a single junction p-n or p-i-n arrangement, the layer arrangement shown in, e.g., FIG. 6 may be preferred. However, when the PV members may have tandem structures or multiple p-n or p-i-n junctions therein, only one lateral electric contact may be necessary for the uppermost and lowermost PV members and, therefore, the layer arrangement of FIG. 7 may be preferred. The above electric contact may be provided by directly contacting charge layers of adjacent PV members and/or through the contact layers as described herein.

Each of the above layers of the PV system may have appropriate lengths and/or thicknesses depending upon design, fabrication, and/or or performance considerations. For example, such layers may be arranged to have identical lengths and thicknesses so that each PV member may generate the same voltage per an amount of the waves projected thereupon. In the alternative, such layers of the PV system may also have different lengths and/or thicknesses. As will be explained in greater detail below, however, the layers having different lengths may be more easier to fabricate than those with different thicknesses. Accordingly, when it is necessary to vary one of the dimensions of each layer, the layer lengths and/or widths may be preferably varied between or among the PV members.

Though the charge layers of the PV members exemplified in the above figures are arranged to have various conductivities and stacked precisely one over the other within each of the PV members, the charge layers within a single PV member may be misaligned along the lateral direction so that the upper layer may not completely cover or may not be disposed precisely above the intermediate and/or lower layers. This misalignment is generally inherent in structures where the vertically stacked upper and lower layers are arranged to have different lengths or widths. Similarly, the PV system may also be arranged to include multiple PV members having different lengths and/or widths. Therefore, when the PV system includes multiple columns of PV members, each column may be arranged to include at least two PV members vertically stacked one over the other, and such columns may be connected in series through the uppermost and/or lowermost contact layers of adjacent columns of PV members. When the PV members may have different lengths and/or widths, some of the PV members within the column may not completely cover or may not be disposed precisely above other PV members of such a column. The nonuniform lengths and/or widths of the charge layers and/or PV members may not be critical to this invention as long as the PV system with such charge layers and/or PV members may be connected in series through their top and/or bottom charge layers or through their uppermost and/or lowermost charge layers and may also be able to generate the driving voltage greater than the voltage generated by each PV member. Similarly, the charge layers of different PV members and having the same or different polarity may be arranged to have different thicknesses. In such an embodiment, the charge layers may be misaligned along the vertical direction such that a charge layer of a PV member may be disposed adjacent to or contact two or more charge layers of another PV member disposed adjacent thereto. Similarly, the PV system may further include multiple columns of PV members having different heights as described above such that the charge layers of each column of PV members are disposed in different elevations compared with such layers of the adjacent column of PV members. The nonuniform thicknesses of the charge layers and/or PV members may be neither critical to this invention as long as the PV system with such charge layers and/or PV members may be connected in series through their top and/or bottom charge layers and/or through their uppermost and/or lowermost charge layers and may also be able to generate the driving voltage greater than the voltage generated by each PV member. It is understood that various insulation layers may further be disposed between the charge layers with nonuniform lengths, widths, and/or thicknesses so as to minimize undesirable formation of short circuits between adjacent charge layers of different polarities.

In addition, the PV members may include different number of charge or planar layers with the same or different shapes and/or sizes. Such PV members may be connected to each other in series by different number of contact layers having different shapes and/or sizes. These charge, planar or contact layers may be misaligned with respect to each other along the lateral and/or vertical direction as described above. The conductivities of these charge and/or planar layers may also be reversed or repeated in a preset order. Additional contact layers, charge transport layers, charge injection layers, insulation layers, optical filter layers, thermal conduction layers, refraction layers, and electrode layers may also be deposited between, over, below or adjacent to the charge, planar, and/or contact layers along the lateral and/or vertical directions. Such charge or planar layers may be made of the same or different materials and/or include the same or different materials in order to control their conductivities and to generate different intensities of voltages. The intermediate layers and/or contact layers may be deposited as a single layer traversing multiple PV members. In addition, the columns of the PV system described hereinabove may include one or more PV members. Each column of the PV system may be constructed to be substantially identical so that each column may generate voltages with substantially identical intensities. Alternatively, the columns of the PV system also may include different number of charge or planar layers and/or different number of PV members to generate voltages having different intensities.

As described above, various charge layers and contact layers may preferably be made planar and monolithic. Accordingly, the layer lengths of these layers may generally be greater than the layer thicknesses thereof, rendering the PV members and the PV systems have lengths which are greater than thicknesses thereof as well. It is appreciated, however, that the PV members and systems may have other lengths, widths, and/or thicknesses and that the above dimensions of the PV members and systems are not critical tot the scope of this invention as long as the PV members may be connected in series by their top and/or bottom charge and/or planar layers or through the contact layers which are disposed at least substantially horizontally with respect to the charge and/or planar layers.

The contact layers may be arranged to extend in a direction not vertically traversing any layer thickness of any of charge and/or planar layers. This arrangement allows deposition of such contact layers slightly angled with respect to the lateral direction. When preferred, the charge and/or planar layers may be deposited at angles in the lateral direction as well. These slanted arrangements may be provided, e.g., by unevenly depositing and/or etching such charge and/or layers, by depositing one or more lateral layer, disposing the layers at angles with respect to the lateral direction, and then etching and/or chipping such layers in the lateral direction, and so on. Similarly, the insulation layers may also be provided to extend substantially in the vertical direction between the upper, intermediate, and lower charge and/or planar layers of the adjacent PV members. It is, therefore, appreciated that, as long as the adjacent PV members include the charge and/or planar layers arranged in a different or opposite order, the shapes and/or sizes of the contact layers and/or insulation layers may not be critical to the scope of this invention and, therefore, may vary from those exemplified in this description.

Different PV members may also include the charge layers, intermediate layers, and/or contact layers which have different configurations (e.g., thicknesses, lengths, widths, and the like) or which are made of materials having different electrical and/or optical properties. Such an arrangement may be particularly useful for the PV system with multiple PV members arranged along the lateral as well as vertical direction. For example, because the solar spectrum covers a range of wavelengths which span from about 300 nanometers to about 2,200 nanometers, few materials may effectively absorb all light rays within the foregoing range. Therefore, each intermediate layer of different PV members may be made of different materials each of which may effectively absorb and convert the light rays within a preset range of wavelengths. For example, some intermediate layers may be made of amorphous Si so that much, if not most, of the light rays in the bandgap of 400 to 900 nanometers may be captured, absorbed, and converted to electricity. Other intermediate layers may then be made of Si germanium so as to absorb most, if not all, of the remaining light rays in the bandgap of 900 to 1,400 nanometers. Therefore, a PV efficiency may be maximized by disposing such layers one over the other or in series along the direction of the light rays. It is understood that the shapes and/or sizes of such intermediate layers may also be determined in order to optimize an amount of electron-hole pairs generated thereby such that, e.g., surface areas with respect to the incoming waves and/or volumes of such layers may be maximized so as to maximize the amount of the electron-hole pairs per unit intensity of the waves. The shapes, sizes, and/or arrangements of such intermediate layers may also be determined based on the needs to insulate neighboring charge layers of adjacent PV members.

It is appreciated that the series connections between the PV members described hereinabove may be applied in conjunction with conventional layer arrangements for PV devices. For example, the PV members may be arranged to form multiple blocks of PV members, where each PV member may be connected to each other in series within each block and where the blocks may be connected to each other in series, in parallel, and/or in combinations. When desirable, the PV members of a block may be connected to each other in parallel as well as far as at least two PV members of such a block may be connected to each other in series through the foregoing contact layer and/or through the uppermost and/or lowermost charge or planar layers thereof.

Such a PV system may be arranged to have a substantially uniform composite refractive index along the lateral and/or vertical direction, although a substantially uniform lateral composite refractory index is more important to various applications. For example, various layers of the PV member may be made of or include materials rendering a composite vertical refractive index of the PV system obtained vertically across an entire thickness of the PV member be at least substantially similar along the lateral direction. Moreover, different PV members may have at least substantially identical composite vertical and/or lateral refractory index so that such a PV system may also have at least substantially identical composite refractory indices along the lateral and/or vertical directions. Alternatively, the PV system may include at least one refraction layer which may be disposed over, below, between or adjacent to other charge, planar, and/or contact layers of the PV members such that a refractive index measured vertically across the entire thickness of the PV system may be substantially similar along the lateral direction.

Similarly, such a PV system may further be arranged to have a substantially uniform composite transmittivity along the lateral and/or vertical direction, though a substantially uniform lateral composite transmittivity is more important to various applications. For example, various layers of the PV member may be comprised of or include materials making a composite vertical transmittivity obtained vertically across an entire thickness of the PV member be at least substantially similar along the lateral direction. Different PV members may further have at least substantially identical composite vertical and/or lateral transmittivity so that the PV system may have at least substantially identical composite transmittivity in the lateral and/or vertical directions. In the alternative, the PV system may further include at least one transmission layer which may be disposed over, below, between or adjacent to other charge, planar, and/or contact layers of the PV members so that a transmittivity measured vertically across the entire thickness of the PV system may be substantially similar along the lateral direction.

Various structures and/or methods of providing the foregoing series connection of the present invention may be applied to conventional semiconductor devices and their fabrication processes. For example, bipolar, MOS, PMOS, NMOS, CMOS, bi-CMOS, FET, MOSFET, IGFET, IGBT, and other devices may include various series connection structures, e.g., through substantially horizontal contact layers, through uppermost and/or lowermost charge or planar layers thereof, and the like. More particularly, when the semiconductor devices having a certain conductivity have to be connected in series, these devices may be deposited or doped in an alternating order of conductivities so that the lateral contact layers may provide series connection therebetween.

The PV system of this invention may also form novel structures when used in conjunction with conventional semiconductor and/or optical devices and may find other novel applications therein. For example, such a PV system may be incorporated into conventional semiconductor devices such as, e.g., bipolar, MOS, PMOS, NMOS, CMOS, bi-CMOS, FET, MOSFET, IGFET, IGBT, and other devices. In addition, the PV system may be incorporated into conventional semiconductive devices so as to form novel, hybrid, self-powering, planar semiconductor devices. Conversely, semiconductor devices may be incorporated into the PV system of this invention so as to manipulate the PV system and to control operations thereof.

In addition, the PV system of the present invention may be combined with various electro-optic or photo-optic devices. Examples of such devices may include, but not be limited to, chemical chromic devices which may change optical properties thereof responsive to temperature, pressure, presence or absence of chemical agents, ph, and the like, photochromic devices which may change their optical properties responsive to the waves impinged thereupon, electro-optic devices such as light-emitting, signal transmitting, and electrochromic devices, and the like. Conventional liquid crystal units may also combined therewith.

The PV system of the present invention and the conventional optical or semiconductor devices described in the preceding paragraphs may be connected in series in the same way as do the multiple PV members of the PV system. That is, the PV members and conventional devices may be deposited or disposed laterally and side by side and connected in series by the horizontal contact layers and/or by the side contact portions of various charge or planar layers described herein. Such PV members may further be deposited over or below the conventional devices to form a column of devices, where such a column of devices may be disposed laterally and adjacent to another column of devices along the lateral direction, whereas the adjacent columns of the PV members and conventional devices may be connected in series by the horizontal contact layers and/or by the side contact portions of various layers. For example, a liquid crystal device may be disposed along the lateral direction and electrically connected with the PV members by the contact layers and/or side contact portions. Alternatively, the PV members and an electrochromic device may also be disposed along the vertical direction one over the other, form a column or stack of planar devices, and be connected in series with each other in the vertical direction. By providing another similar column of the PV members and any conventional planar devices adjacent to the column and by matching the conductivities of the uppermost and lowermost layers thereof, multiple planar devices may be connected in series, e.g., by contact layers extending along the lateral direction, by the side contact portions of the uppermost or the lowermost layers, and so on. When desirable, the contact layers may also be disposed over or below the uppermost and/or lowermost layers. The side contact portions may be formed in the layers sandwiched between other layers as well. Therefore, the above PV members and conventional devices may form an aggregate of planar devices which may operate as independent units capable of powering themselves.

The PV system may include numerous PV members arranged in rows, columns, and/or arrays thereof and, as a result, the PV system may include hundreds or thousands of photovoltaic cells each of which is capable of generating voltage for a variety of applications. Interconnection tabs or vertical interconnects of the PV cells may be provided between the PV members or between clusters thereof so as to conduct electricity from one to another in series and/or in parallel. Vertical interconnects may be manufactured through conventional methods, e.g., by punching or etching conductive strips and/or sheets to a desired configuration which are generally less than 0.05 mm thick and attached to the PV cells by extremely time consuming processes of manual soldering or welding or by an elaborate and expensive automated process. Other than being highly labor intensive, welding or soldering of such delicate interconnects to the PV cells is generally a high risk procedure, resulting in frequent breakage of the expensive PV cells and a high rate of attrition during the fabrication process. In order to rectify such problems, the present invention provides novel series connection structures of the PV system and methods thereof, where multiple PV members may be disposed substantially laterally and side by side, where the charge layers of the PV members are arranged to have conductivities arranged in an alternating order, where the charge layers of adjacent PV members have conductivities arranged in opposite orders, and where the upper and lower charge layers having opposite conductivities may be connected in series through their sides, through the horizontal contact layers or through side contact portions thereof. When compared with the conventional methods of simpler layer deposition but more complicated vertical interconnect, the present invention provides simpler methods of connecting such charge or planar layers of alternating conductivities at the cost of more complex deposition of layers. Therefore, when the PV devices such as low-grade PV cells are required, the solar panels provided by the conventional method may be relatively inexpensively connected in series by external lead-out wires. However, when the PV devices or conventional semiconductor or electro-optic devices must be prepared with a greater precision or require the complicated layer structure and/or multiple vertical interconnects, the PV system of the present invention may be effectively applied.

It is to be understood that, while various aspects and embodiments of the present invention have been described in conjunction with the detailed description thereof, the foregoing description is intended to illustrate and not to limit the scope of the invention, which is defined by the scope of the appended claims. Other embodiments, aspects, advantages, and modifications are within the scope of the following claims.

1. A photovoltaic system capable of generating driving voltage in response to electromagnetic waves impinged thereupon comprising:
a plurality of photovoltaic members each of which is configured to include a plurality of charge layers, wherein said members are configured to be disposed laterally and side by side, wherein said charge layers of each of said members are configured to be disposed vertically and contacting each other and to have different polarities arranged in a preset order so as to generate voltage in response to said waves, wherein at least two of said members are configured to be disposed adjacent to each other, to generate said voltages in opposite vertical direction, and to be connected in series by on of their top and bottom charge layers so as to enable said system to generate said driving voltage which is greater than each of said voltages generated by said members.

2. The photovoltaic system of claim 1, wherein said preset order of said polarities of said charge layers of one of said adjacent members is configured to be at least partially opposite to said preset order of said polarities of said charge layers of the other of said adjacent members.

3. The photovoltaic system of claim 1 further comprising at least one of a top contact layer and a bottom contact layer, wherein said top contact layer is configured to be disposed over and to connect top charge layers of said adjacent members, and wherein said bottom contact layer is configured to be disposed below and to connect bottom charge layers of said adjacent members.

4. The photovoltaic system of claim 3, wherein said top and bottom contact layers are configured to not vertically traverse more than one of said charge layers.

5. The photovoltaic system of claim 1, wherein each of said members is configured to include at least substantially similar number of said charge layers and to have substantially similar transmittivity to said waves, and wherein said system is configured to have said transmittivity at least substantially uniform through its horizontal length.

6. The photovoltaic system of claim 1, wherein said members are configured to be connected to each other by at least one of series and parallel connection and to generate said voltages at least substantially independently of each other such that said system is configured to generate said driving voltages when at least one of said members is configured to be disconnected from others thereof.

7. The photovoltaic system of claim 6, wherein at least a substantial number of said members are configured as a plurality of member groups, wherein a preset number of said members are configured to be connected in series in each of said member groups in order to generate said driving voltage, and wherein said member groups are configured to be connected in parallel so that said system is capable of generating said driving voltage even when at least some of said members are disabled.

8. The photovoltaic system of claim 1, wherein at least a substantial number of said members are configured to be at least partially transparent and said system at least partially transparent, wherein said system is disposed over at least a portion of an at least partially transparent article which is one of a lens and a sheet of glass, and wherein said system is configured to supply said driving voltage to said article.

9. A planar photovoltaic system for generating a driving voltage in response to electromagnetic waves impinged thereupon and capable of transmitting at least a portion of said waves therethrough, said system configured to include a plurality of photovoltaic members and to be defined in a plurality of planar layers configured to be disposed vertically one over the other and to contact each other, said system comprising:
a first photovoltaic member configured to be defined vertically across a first zone of at least two of said planar layers contacting each other, wherein said planar layers of said first member are configured to be at least partially transparent and to have different polarities arranged in a first order to generate first voltage in response to said waves; and
a second photovoltaic member configured to be defined vertically across a second zone of said at least two layers and to be defined laterally adjacent to said first member, wherein said planar layers of said second member are configured to be at least partially transparent and to have different polarities arranged in a second order to generate second voltage in response to said waves,
wherein said first and second members are configured to be connected in series by their top planar layers in order to enable said system to generate said driving voltage greater than each of said first and second voltages.

10. The photovoltaic system of claim 9, wherein said first order of polarities of said planar layers of said first member is configured to be at least partially opposite to said second order of polarities of said planar layers of said second member.

11. The photovoltaic system of claim 9 further comprising at least one of a top contact layer and a bottom contact layer, wherein said top contact layer is configured to be disposed over and to connect top planar layers of said first and second members and said bottom contact layer is configured to be disposed below and to connect bottom planar layers of said first and second members.

12. The photovoltaic system of claim 11, wherein neither of said top and bottom contact layers is configured to vertically traverse more than one of said planar layers.

13. The photovoltaic system of claim 9, wherein said first and second members are configured to include at least substantially similar number of said planar layers and, therefore, to have substantially similar transmittivities to said waves such that said system is configured to have said transmittivity at least substantially uniform along its horizontal length.

14. The photovoltaic system of claim 9, wherein said first and second members are configured to be connected to each other through at least one of a series connection and a parallel connection and to generate said voltages at least substantially independently of each other such that said system is capable of to generating said driving voltage even when at least one of said members is configured to be disconnected from the rest thereof.

15. The photovoltaic system of claim 14, wherein said system include a plurality of said first and second members, wherein said first and second members are configured into a plurality of member groups, wherein a preset number of said members are configured to be connected in series in each of said member groups so as to generate said driving voltage, and wherein said member groups are configured to be connected in parallel so that said system is capable of generating said driving voltage even when at least some of said members are disabled.

16. The photovoltaic system of claim 9, wherein said first and second members are configured to be at least partially transparent to render said system at least partially transparent.

17. The photovoltaic system of claim 16, wherein said system is disposed over at least a portion of an at least partially transparent article which is one of a lens and a sheet of glass and wherein said system is configured to supply said driving voltage to said article.

18. The photovoltaic system of claim 9, wherein at least a portion of said system is configured to be at least one of elastic and deformable.

19. The photovoltaic system of claim 9 further comprising a switch configured to operate between an on-state and an off-state, wherein said switch is configured to supply said driving voltage from said system to an article over which said system is disposed in said on-state and to stop supplying said system from said article in said off-state.

20. A method of providing a plurality of planar photovoltaic members connected in series without employing vertical interconnects comprising the steps of:
depositing a first planar layer;
doping a first region of said first planar layer into a first polarity of a first order of polarities;
doping a second region of said first planar layer into a first polarity of a second order of said polarities, wherein said second order is configured to be at least partially opposite to said first order;
depositing a second planar layer over said first planar layer;
doping a first region of said second planar layer configured to at least partially overlap with said first region of said first planar layer into a second polarity of said first order;
doping a second region of said second planar layer configured to at least partially overlap with said second region of said first planar layer into a second polarity of said second order;
repeating said depositing and doping until said regions of said planar layers including said first region are configured to form a first member completing said first order and until said regions of said planar layers including said second region are configured to form a second member completing said second order; and
connecting said members in series by connecting one of top planar layers and bottom planar layers of said members.
